(19) United States
(12) Patent Application Publication
(10) Pub. No.: US 2026/0150379 A1
(43) Pub. Date: May 28, 2026

(54) MEMORY DEVICE HAVING A REACTIVE LAYER AND METHOD OF MANUFACTURING THE SAME

(71) Applicant: Samsung Electronics Co., Ltd., Suwon-si (KR)

(72) Inventor: Hyun-Mook CHOI, Suwon-si (KR)

(21) Appl. No.: 19/343,469

(22) Filed: Sep. 29, 2025

(30) Foreign Application Priority Data
Nov. 22, 2024 (KR) 10-2024-0168729

(51) Int. Cl. H10D 64/68; H10B 51/10; H10B 51/30; H10D 64/01

(52) U.S. Cl. CPC H10D 64/689; H10B 51/10; H10B 51/30; H10D 64/033

(57) ABSTRACT

Provided is a memory device including a substrate, a channel layer on the substrate and extending in a first direction intersecting a top surface of the substrate, a plurality of gate electrodes arranged along the first direction, each gate electrode disposed on the channel layer, a plurality of ferroelectric layer, each ferroelectric layer between the channel layer and a respective gate electrode, and a reactive layer between each gate electrode and a respective ferroelectric layer, the reactive layer including a reactive metal, wherein ferroelectric layers adjacent to each other from among the plurality of ferroelectric layers are spaced apart from each other in the first direction.

### CROSS-REFERENCE TO RELATED APPLICATIONS

This application claims the benefit of Korean Patent Application No. 10-2024-0168729, filed on Nov. 22, 2024, in the Korean Intellectual Property Office, the disclosure of which is incorporated herein by reference in its entirety.

### BACKGROUND

### 1. Field of the Invention

Example embodiments relate to a memory device.

### 2. Description of the Related Art

NAND flash is evolving in the direction of improving integration, operation speed, and yield. To achieve higher integration of NAND flash, vertical NAND (VNAND) has been proposed. Additionally, NAND flash with ferroelectrics has also been proposed to offer advantages such as lower driving voltage and faster programming speed.

### SUMMARY

An aspect provides a memory device that is capable of preventing

deterioration of cell properties, minimizing interruption between cells, and improving polarization properties of ferroelectrics.

However, the goals to be achieved by example embodiments of the present disclosure are not limited to the objectives described herein and other objects may be clearly understood from the following example embodiments by those skilled in the art.

According to an aspect, there is provided a memory device including a substrate, a channel layer on the substrate and extending in a first direction intersecting a top surface of the substrate, a plurality of gate electrodes arranged along the first direction, each gate electrode disposed on the channel layer, a plurality of ferroelectric layers each ferroelectric layer between the channel layer and a respective gate electrode, a reactive layer between each gate electrode and a respective ferroelectric layer, the reactive layer including a reactive metal, wherein ferroelectric layers adjacent to each other among the plurality of ferroelectric layers may be spaced apart from each other in the first direction.

According to another aspect, there is also provided a method of manufacturing a memory device including forming a laminated body of an insulating layer and a dielectric layer alternately laminated in a first direction, forming a hole in the laminated body, the hole extending in a first direction and partially removing the dielectric layer a second direction in which the dielectric layer is extended, the second direction crossing the first direction, forming a reactive layer which overlaps with the dielectric layer in the second direction, the reactive layer including a reactive metal, forming a ferroelectric layer on the reactive layer, forming a channel layer extending within the hole in the first direction, and replacing the dielectric layer with a gate electrode.

According to still another aspect, there is also provided a memory device including a substrate, a channel layer on the substrate, extending in a first direction intersecting a top surface of the substrate, and including a plurality of regions having different thicknesses in a second direction parallel to the top surface of the substrate, a plurality of gate electrodes arranged along the first direction, each gate electrode disposed on the channel layer, a plurality of insulating layers overlapping with the plurality of gate electrodes when viewed from the first direction, a plurality of ferroelectric layers each ferroelectric layer between the channel layer and a respective gate electrode, and a reactive layer between each gate electrode and a respective ferroelectric layer, the reactive layer including a reactive metal, wherein ferroelectric layers adjacent to each other among the plurality of ferroelectric layers are spaced apart from each other in the first direction, the reactive metal includes one or more of titanium (Ti), erbium (Er), cobalt (Co), and cadmium (Cd), gate electrodes adjacent to each other among the plurality of gate electrodes are spaced apart from each other in the first direction, and the insulating layers are disposed between adjacent spaced apart gate electrodes among the plurality of gate electrodes.

Detailed descriptions of other example embodiments are included in the detailed description and drawings.

### BRIEF DESCRIPTION OF THE FIGURES

These and/or other aspects, features, and advantages of the application will become apparent and more readily appreciated from the following description of example embodiments, taken in conjunction with the accompanying drawings of which:

FIG. 1 is a circuit diagram illustrating a portion of a circuit of a memory device according to an example embodiment of the present disclosure;

FIG. 2 is an example diagram illustrating a cross-section of a memory device according to a first example embodiment of the present disclosure;

FIG. 3 is an example diagram illustrating a cross-section taken along line A-A′ of FIG. 2;

FIG. 4 is an example diagram illustrating a cross-section taken along line B-B′ of FIG. 2;

FIG. 5 is an example diagram illustrating a cross-section of a memory device according to a second example embodiment of the present disclosure;

FIG. 6 is an example diagram illustrating a cross-section taken along line C-C′ of FIG. 5;

FIG. 7 is an example diagram illustrating a cross-section of a memory device according to a third example embodiment of the present disclosure;

FIG. 8 is an example diagram illustrating a cross-section take along line D-D′ of FIG. 7;

FIG. 9 is an example diagram illustrating a cross-section taken along line E-E′ of FIG. 7;

FIG. 10 is an example diagram illustrating a cross-section of a memory device according to a fourth example embodiment of the present disclosure;

FIG. 11 is an example diagram illustrating a cross-section taken along line F-F′ of FIG. 10;

FIGS. 12 through 28 are example diagrams for describing a method of manufacturing a memory device according to a first example embodiment to a fourth example embodiment of the present disclosure;

FIG. 29 is an example diagram illustrating a cross-section of a memory device according to a fifth example embodiment of the present disclosure;

FIG. 30 is an example diagram illustrating across-section taken along line G-G′ of FIG. 29;

FIG. 31 is an example diagram illustrating a cross-section of a memory device according to a sixth example embodiment of the present disclosure;

FIG. 32 is an example diagram illustrating a cross-section of a memory device according to a seventh example embodiment of the present disclosure;

FIG. 33 is an example diagram illustrating a cross-section of a memory device according to an eighth example embodiment of the present disclosure; and

FIGS. 34 through 50 are example diagrams illustrating a method of manufacturing a memory device according to a fifth example embodiment to eighth example embodiment of the present disclosure.

### DETAILED DESCRIPTION

Example embodiments described in the present disclosure and configurations illustrated in the accompanying drawings are example embodiments and may not represent all aspects of the technical spirit of the present disclosure. Thus, various equivalents and modifications that may replace the example embodiments and configurations may be present at the time of filing the application of the present disclosure.

The same reference numerals or symbols shown in each drawing of the present specification may indicate parts or components that perform substantially the same function. For ease of explanation and understanding, different example embodiments may be described using the same reference numerals or symbols. For example, even though components having the same reference numerals are shown in the plurality of drawings, the plurality of drawings may not indicate one example embodiment.

The drawings illustrated in the present disclosure are according to example embodiments, and the ratio of the width, the length and the height (or the thickness) of each element is for detailed descriptions for the example embodiments, and thus the ratio may differ. Further, in the coordinate system illustrated in the drawings, each axis may be perpendicular to each other, and the direction the arrow points may be the + direction, and the direction opposite to the direction indicated by the arrow (rotated by 180 degrees) may be the − direction.

In the present disclosure, when a component is referred to as being “in contact with” or “contacting” another component, it may be understood that the component is in direct contact with or connected to the other component and it may be understood that no other components exist between them.

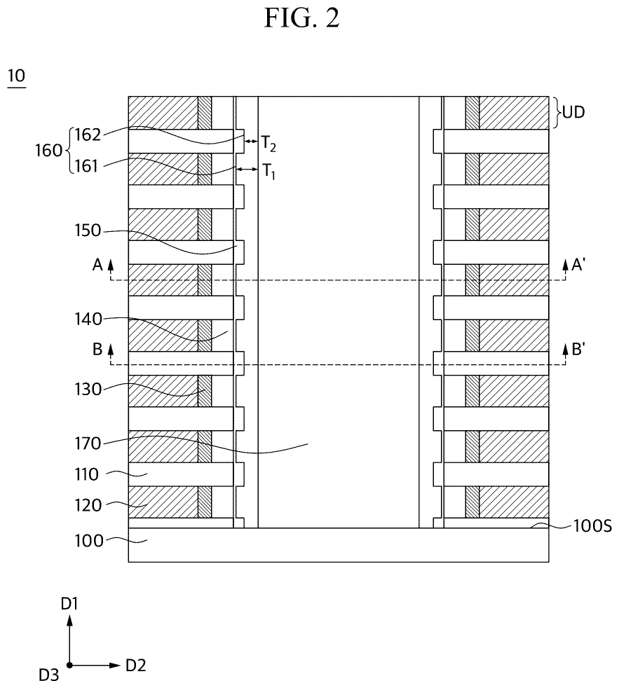

Also, in the present disclosure, when a component is referred to as being “above” another component, it may be understood that the component is present over the other component in a vertical direction. For example, the component may be understood as being over the other component in a direction +D1 of a diagram (e.g., FIG. 2). The components may be in contact with one another or another component may be present between them.

Also spatially relative terms such as “above” and “below” as used herein have their ordinary broad meanings—for example element A can be above element B even if when looking down on the two elements there is no overlap between them (just as something in the sky is generally above something on the ground, even if it is not directly above). Items described as “vertically overlapping” are at least in part directly above or below each other along a vertical direction (e.g., the D1 direction). As used herein, components described as being “electrically connected” are configured such that an electrical signal can be transferred from one component to the other (although such electrical signal may be attenuated in strength as it is transferred and may be selectively transferred).

Other expressions for describing a relationship between positions of components may be the same as described with respect to other embodiments herein.

In the following descriptions, terms in a singular form may refer to a plurality of items unless an apparently and contextually conflicting description is present. Terms such as “including” or “comprising” indicate that a feature, a number, an operation, an action, a component, a part, or a combination thereof is present. It is to be understood that these terms may mean that the component may be formed of only the element or the group of elements, or that the element or group of elements may be combined with additional elements to form the component. The terms are not to exclude in advance a possibility that one or more other features, numbers, operations, actions, component, parts, or combinations thereof may be present or added.

Terms including an ordinal number such as “first” or “second” may be used in the present disclosure to distinguish between elements from each other. The ordinal number may be used to distinguish between identical or similar elements, and the meanings of the terms may not be limited by use of the ordinal number. For example, a use order, a disposition order, or the like of elements with such an ordinal number may not be limitedly construed by the number. As required, each ordinal number may be substituted with each other. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

As used herein the terms “overlap” or “overlap with” or “overlapping” or “on”, are intended to mean that an element is at least partially on another element. The elements may be touching or not. For example, there may be layers between layers that are overlapping with or on one another. An element “overlapping” or “on” another element need not cover or overlap with an entire surface of another element to be considered “overlapping”. The terms are intended to encompass one element “overlapping” or “on” all, or any part of, an element it overlaps with.

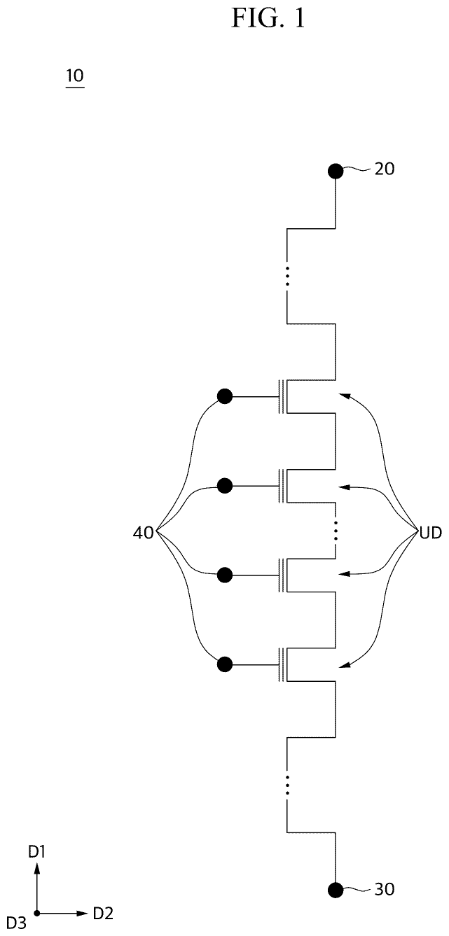

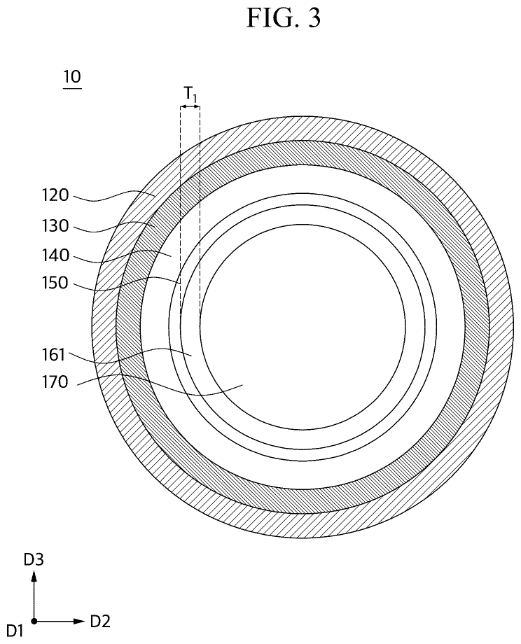

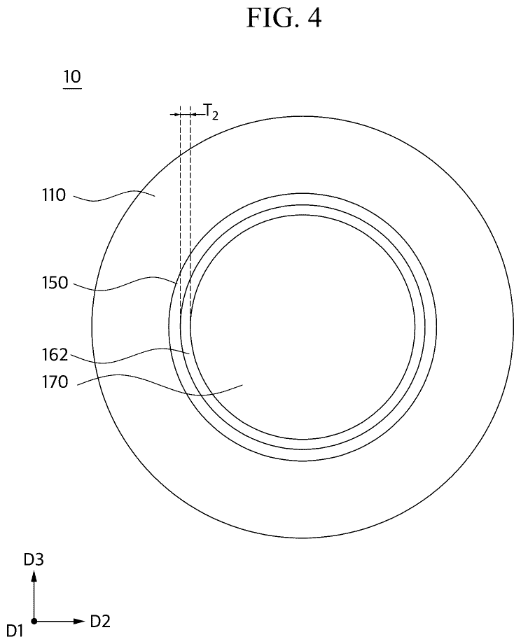

FIG. 1 is a circuit diagram illustrating a portion of a circuit of a memory device 10 according to an example embodiment of the present disclosure. FIG. 2 is an example diagram illustrating a cross-section of the memory device 10 according to a first example embodiment of the present disclosure. FIG. 3 is an example diagram illustrating a cross-section taken along line A-A′ of FIG. 2. FIG. 4 is an example diagram illustrating a cross-section taken along line B-B′ of FIG. 2.

A first direction D1 may refer to a direction crossing a surface 100S of a substrate unless otherwise specified. For example, the first direction D1 may refer to a direction perpendicular to the surface 100S of the substrate. A second direction D2 may refer to a direction parallel to the surface 100S of the substrate, the second direction crossing the first direction D1. A third direction D3 may refer to a direction parallel to the surface 100S of the substrate, the third direction crossing the first direction D1 and the second direction D2.

In an example embodiment, the memory device 10 may include a unit device UD. The unit device UD may be electrically connected to a word line 40. In an example embodiment, the memory device 10 may include a plurality of unit devices UD connected to a plurality of respective word lines 40. A first group of unit devices of the plurality of unit devices UD may be connected in series and at least another portion of the plurality of unit devices UD may be connected in parallel.

In an example embodiment, the memory device 10 may include a drain region 20 and a source region 30. The drain region 20 and the source region 30 may be spaced apart from each other. The drain region 20 and the source region 30 may be spaced apart from each other in the first direction D1.

In an example embodiment, the unit device UD (or a plurality of unit devices) may be disposed between the drain region 20 and the source region 30. In embodiments having a plurality of unit devices, the plurality of unit devices UD may be spaced apart from each other in the first direction D1. For example, the plurality of unit devices UD may be arranged vertically above a substrate 100. Unit devices UD adjacent to the drain region 20 and the source region 30 may be spaced apart from the drain region 20 or the source region 30, respectively.

In an example embodiment, the unit device UD may be electrically connected to the drain region 20 and the source region 30. Although not illustrated in the drawings, the memory device 10 may be electrically connected to a body line which applies a voltage to the substrate 100.

In an example embodiment, the drain region 20 and the source region 30 may include an identical type of a semiconductor material. In some examples, the drain region 20 and the source region 30 may include different types of conductive materials. The drain region 20 and the source region 30 may each independently include one or more of a p-type semiconductor material and an n-type semiconductor material. The p-type semiconductor material may include a dopant containing at least one of boron (B) and gallium (Ga) and the n-type semiconductor material may include a dopant containing at least one of phosphorus (P), arsenic (As), antimony (Sb), and bismuth (Bi).

In an example embodiment, the drain region 20 and the source region 30 may include a semiconductor material of an identical type, and the substrate 100 may include a semiconductor material of a type different from that of the drain region 20 and the source region 30, but this is merely an example. In an example embodiment, the drain region 20 and the source region 30 may include a semiconductor material of a different type, and the substrate 100 may include a semiconductor material of a type different from that of the drain region 20 and the source region 30, but this is merely an example.

In an example embodiment, the memory device 10 for example, may be a non-volatile memory device. In an example embodiment, the non-volatile memory device for example, may be a flash memory, a read-only memory (ROM), a hard disk, a diskette drive, a magnetic tape, or an optical disc, but these are merely examples. In an example embodiment, the non-volatile memory device may be a flash memory. In an example embodiment, the flash memory may be a NAND flash memory or, more specifically, a vertical NAND flash memory. In an example embodiment, the memory device 10 may be the vertical NAND flash memory, but this is merely an example.

In an example embodiment, the memory device 10 may include the substrate 100, a channel layer 160, a gate electrode 120, a ferroelectric layer 140, and a reactive layer 130.

In an example embodiment, the substrate 100 may be bulk silicon or silicon-on-insulator (SOI). Alternatively, the substrate 100 may be a silicon substrate or may include other material, for example, silicon germanium, silicon germanium on insulator (SGOI), indium antimonide, lead telluride compound, indium arsenide, indium phosphide, gallium arsenide, or gallium antimonide, but these are merely examples.

In an example embodiment, the channel layer 160 may be disposed above the substrate 100. The channel layer 160 may be formed to extend in the first direction D1. For example, the channel layer 160 may be formed to extend in a direction crossing (for example, perpendicular to) the surface 100S of the substrate. In an example embodiment, the channel layer 160 may have a hollow cylindrical shape.

In an example embodiment, the channel layer 160 may include one or more of silicon (Si) and germanium (Ge). The channel layer 160 may include a compound semiconductor in some cases, and for example, may include a group IV-IV compound semiconductor or a group III-V compound semiconductor.

In an example embodiment, the group IV-IV compound semiconductor for example, may be a binary compound or a ternary compound which includes at least two of carbon (C), silicon (Si), germanium (Ge), and tin (Sn), or a compound doped with a group IV element thereto, but these are merely examples. In an example embodiment, the group III-V compound semiconductor for example, may be one of a binary compound, a ternary compound, or a quaternary compound formed by combining at least one of aluminum (Al), gallium (Ga), and indium (In) which are group III elements and one of phosphorus (P), arsenic (As), and antimony (Sb) which are group V elements, but these are merely examples.

In an example embodiment, the channel layer 160 may include one of poly-silicon, indium oxide, tin oxide, zinc oxide, In-zinc (Zn) based oxide, tin (Sn)—Zn based oxide, aluminum (Al)—Zn based oxide, Zn-magnesium (Mg) based oxide, Sn—Mg based oxide, In—Mg based oxide, In—Ga based oxide (IGO), In—Ga—Zn based oxide (GIZO), In—Al—Zn based oxide, In—Sn—Zn based oxide, Sn—Ga—Zn based oxide, Al—Ga—Zn based oxide, Sn—Al—Zn based oxide, In-hafnium (Hf)—Zn based oxide, In-lanthanum (la)—Zn based oxide, In-cerium (Ce)—Zn based oxide, In-praseodymium (Pr)—Zn based oxide, In-neodymium (Nd)—Zn based oxide, In-samarium (Sm)—Zn based oxide, In-europium (Eu)—Zn based oxide, In-gadolinium (Gd)—Zn based oxide, In-terbium (Tb)—Zn based oxide, In-dysprosium (Dy)—Zn based oxide, In-holmium (Ho)—Zn based oxide, In-erbium (Er)—Zn based oxide, In-thulium (Tm)—Zn based oxide, In-ytterbium (Yb)—Zn based oxide, In-lutetium (Lu)—Zn based oxide, In—Sn—Ga—Zn based oxide, In—Hf—Ga—Zn based oxide, In—Al—Ga—Zn based oxide, In—Sn—Al—Zn based oxide, In—Sn—Hf—Zn based oxide, and In—Hf—Al—Zn based oxide, but these are merely examples.

In an example embodiment, the gate electrode 120 may be disposed above the channel layer 160. In an example embodiment, the gate electrode 120 may surround at least a portion of the channel layer 160.

In an example embodiment, the gate electrode 120 may be a plurality of gate electrodes 120 including the gate electrode 120 and gate electrodes 120 adjacent to each other among the plurality of gate electrodes 120 may be spaced apart in the first direction D1.

In an example embodiment, the gate electrode 120 may include a conductive material. The conductive material in the present disclosure may have, for example, an electrical conductivity of 10⁶ S/m or higher when measured at a normal temperature. In the present disclosure, the electrical conductivity may be measured based on ASTM E 1004, but this is merely an example. For example, the conductive material may include at least one of a metal, a metal alloy, a conductive metal nitride, a metal silicide, a doped semiconductor material, a conductive metal oxide, and a conductive metal oxynitride. For example, the conductive material may include one or more conductive materials selected from a group comprising titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN) tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (NoC), tungsten carbide (WC), rhodium (Rh), palladium (Pd), iridium (Ir), osmium (Os), silver (Ag), gold (Au), zinc (Zn), and vanadium (V), but these are merely examples. The conductive metal oxide and the conductive metal oxynitride may include an oxidized form of the described material, but this is merely an example.

In an example embodiment, the memory device 10 may include an insulating layer 110 which overlaps with the gate electrode 120 in at least a region when viewed from the first direction D1. The insulating layer 110 may not overlap with the gate electrode 120 when viewed from the second direction D2. The insulating layer 110 may be disposed to fill a space between the gate electrodes 120 adjacent to each other and spaced apart. The insulating layer 110 may include a plurality of insulating layers.

In an example embodiment, the insulating layer 110 may be disposed above the channel layer 160 (e.g., on an outer surface of the channel layer 160). The insulating layer 110 may surround at least a portion of the channel layer 160.

In an example embodiment, a second region (162, for example) of the channel layer 160 surrounded by the insulating layer 110 and a first region (161, for example) of the channel layer 160 surrounded by the ferroelectric layer 140 may not overlap with each other.

In an example embodiment, the insulating layer 110 may overlap with at least a portion of the ferroelectric layer 140 when viewed from the first direction D1. The insulating layer 110 may not overlap with the ferroelectric layer 140 when viewed from the second direction D2.

In an example embodiment, the insulating layer 110 may include an insulating material. In the present disclosure, the insulating material may have an electrical conductivity of 10⁻⁶ S/m or lower. For example, the insulating material may include one or more selected from a group comprising silicon oxide, silicon-germanium oxide, germanium oxide, silicon oxynitride, silicon nitride, a high dielectric material with higher dielectric constant than that of silicon nitride, or a low dielectric material with lower dielectric constant than that of silicon nitride. The high dielectric material, for example, may include one or more from a group comprising boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but these are merely examples. The low dielectric material, for example, may include one or more from a group comprising fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen silazen (TOSZ), fluoride silicate glass (FSG), polyimide nanofoams such as polypropylene oxide, carbon doped silicon oxide (CDO), OSG organo silicate glass (OSG), silicon lithium potassium (SiLiK), amorphous fluorinated carbon, silica aerogels, silica xerogels, and mesoporous silica, but these are merely examples.

In an example embodiment, the ferroelectric layer 140 may include or be a plurality of ferroelectric layers 140. As can be seen for Example in FIG. 2, the plurality of ferroelectric layers 140 may be disposed between the channel layer 160 and the gate electrode 120. Ferroelectric layers 140 adjacent to each other among the plurality of ferroelectric layers 140 may be spaced apart in the first direction D1.

In an example embodiment, the ferroelectric layer 140 may surround at least a portion of the channel layer 160. The insulating layer 110 may be disposed to fill a space between the ferroelectric layers 140 adjacent to each other and spaced apart.

In an example embodiment, the ferroelectric layer 140 may include ferroelectrics. In an example embodiment, the ferroelectrics may have a spontaneous polarization property due to an application of an electric field and may have a remnant polarization even in a state in which the electric field is not present after having the spontaneous polarization property. In an example embodiment, the ferroelectrics may include a compound that includes one or more of hafnium and zirconium and that has a ferroelectric property. In an example embodiment, the ferroelectrics may include hafnium oxide (HfO) which is a compound including hafnium (Hf), zirconium oxide (ZrO) which is a compound including zirconium (Zr), or hafnium-zirconium oxide (HZO) which is a compound including hafnium (Hf) and zirconium (Zr). In an example embodiment, the ferroelectrics are not limited to the above-listed compounds and may include one or more compounds selected from a group comprising BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, BaSrTiO₃, HF0·5Zr0·5O₂, PbZrₓTi₁₋ₓO₃ (0<x<1), Ba(Sr, Ti)O₃, Bi₄-xLaₓTi₃O₁₂(0<x<1), SrBi₂Ta₂O₉, Pb₅Ge₅O₁₁, SrBi₂Nb₂O₉, and YMnO₃. In an example embodiment, the ferroelectrics may include an orthorhombic crystal system. In an example embodiment, the ferroelectrics may include a compound doped with impurities, and the impurities may include one or more impurities selected from a group comprising carbon (C), silicon (Si), magnesium (Mg), aluminum (Al), yttrium (Y), nitrogen (N), germanium (Ge) and tin (Sn), gadolinium (Gd), lanthanum (La), scandium (Sc) and strontium (Sr).

In an example embodiment, the reactive layer 130 may be disposed between the gate electrode 120 and the ferroelectric layer 140, for example in the second direction D2. In example embodiments, the reactive layer 130 may be in contact with the gate electrode 120 in at least a region. In example embodiments, the reactive layer 130 may be in contact with the ferroelectric layer 140 in at least a region. The reactive layer 130 may surround at least a portion of the ferroelectric layer 140.

In an example embodiment, the reactive layer 130 may include a reactive metal. In the present disclosure, although the reactive metal is not particularly limited, if the reactive metal is a metal that reacts with the oxygen existing in an oxide, the reactive metal may include or be one or more of titanium (Ti), erbium (Er), cobalt (Co), and cadmium (Cd).

Referring to FIGS. 2 through 4, the reactive layer 130 may include a plurality of reactive layers 130. The plurality of reactive layers 130 may be disposed in a region corresponding to the ferroelectric layer 140. Reactive layers 130 adjacent to each other among the plurality of reactive layers 130 may be spaced apart in the first direction D1. Here, the reactive layer 130 and the ferroelectric layer 140 may overlap with each other when viewed from the second direction D2.

In an example embodiment, the memory device 10 may include an interlayer 150 which is disposed between the ferroelectric layer 140 and the channel layer 160. The interlayer 150 may be disposed in one or more of a space between the ferroelectric layer 140 and the channel layer 160 and a space between the insulating layer 110 and the channel layer 160. The interlayer 150 may be formed to extend in the first direction D1. The interlayer 150 may surround at least a portion of the ferroelectric layer 140. The channel layer 160 may surround at least a portion of the interlayer 150. The interlayer 150 may include, for example, an oxide. The interlayer 150 may include an oxide of a material included in the channel layer 160.

In an example embodiment, the reactive layer 130 may react with the oxygen present in an oxide, and may include an oxide of a reactive metal as a result. In an example embodiment, the reactive layer 130 may react with the oxygen of an oxide included in the interlayer 150. The reactive layer 130 may include a greater or higher mass content of the reactive metal than the mass content of the oxide of the reactive metal.

In an example embodiment, the channel layer 160 may include a plurality of regions 161 and 162 having different thicknesses in the second direction D2. The reactive layer 130 may react with the oxygen of the oxide included in the interlayer 150 and a portion of the interlayer 150 may be reduced to a material included in the channel layer 160 as a result. As a result, the channel layer 160 may have a different thickness in the second direction D2 due to the reactive layer 130.

In an example embodiment, a thickness T₁ of a first region 161 of the channel layer 160 in the second direction D2 that corresponds to the ferroelectric layer 140 may be greater than a thickness T₂ of a second region 162 of the channel layer 160 in the second direction D2 which is different from the first region 161.

In an example embodiment, the memory device 10 may include a filling layer 170 which is surrounded by the channel layer 160. In an example embodiment, the filling layer 170 may include an insulating material. In some cases, the filling layer 170 may include air or other gases (e.g., such as those present during manufacturing) or may comprise a gap forming a vacuum therein. In an example embodiment, the filling layer 170 may be formed to extend in the first direction D1.

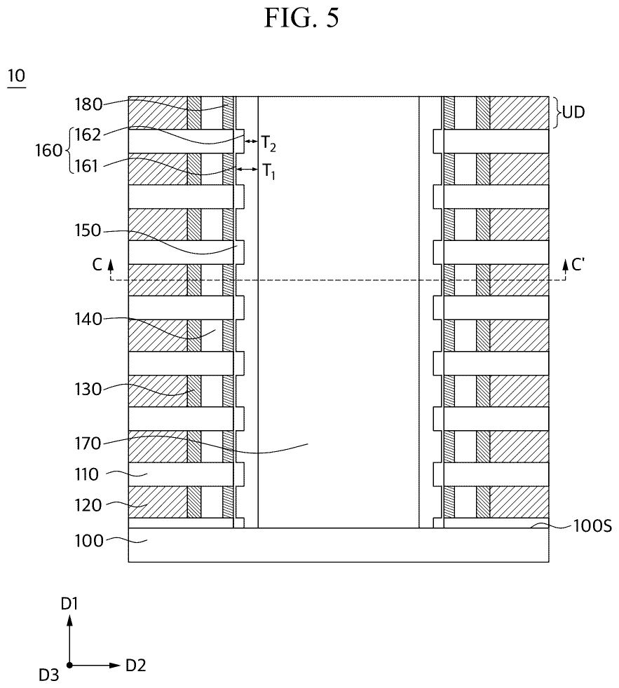

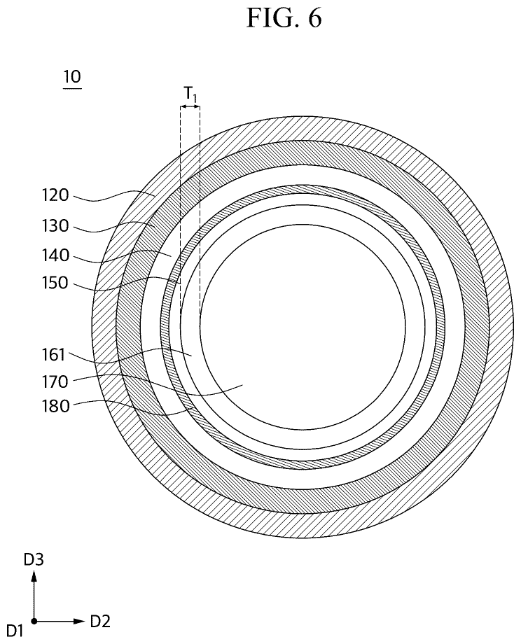

FIG. 5 is an example drawing illustrating a cross-section of the memory device 10 according to a second example embodiment of the present disclosure. FIG. 6 is an example diagram illustrating a cross-section taken along line C-C′ of FIG. 5. The description of FIGS. 1 through 4 may be referenced in the description of FIGS. 5 and 6 unless otherwise specified.

In an example embodiment, the memory device 10 may include a conductive layer 180 which is disposed between the channel layer 160 and the ferroelectric layer 140. The conductive layer 180 may surround at least a portion of the channel layer 160. The conductive layer 180 may be in contact with the ferroelectric layer 140 in at least a region. The conductive layer 180 may enhance a spontaneous polarization property of the ferroelectric layer 140.

In an example embodiment, the conductive layer 180 may include a conductive material. For example, the conductive material included in the conductive layer 180 may be identical to a conductive material included in the gate electrode 120. In an example embodiment, a thickness of the gate electrode 120 in the second direction D2 may be greater than a thickness of the conductive layer 180 in the second direction D2.

In an example embodiment, the conductive layer 180 may include a plurality of conductive layers 180 including the conductive layer 180. Conductive layers 180 adjacent to each other among the plurality of conductive layers 180 may be spaced apart in the first direction D1. The insulating layer 110 may be disposed to fill at least a portion of a space between the conductive layers 180 adjacent to each other and spaced apart.

In an example embodiment, the conductive layer 180 may overlap with the reactive layer 130 when viewed from the second direction D2. In example embodiments, the conductive layer 180 may overlap with the ferroelectric layer 140 when viewed from the second direction D2. The conductive layer 180 may overlap with the gate electrode 120 in at least a region when viewed from the second direction D2.

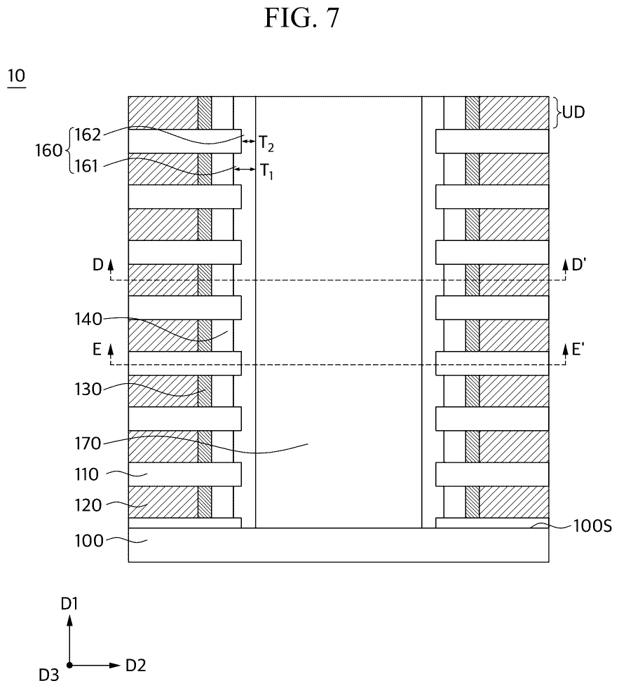

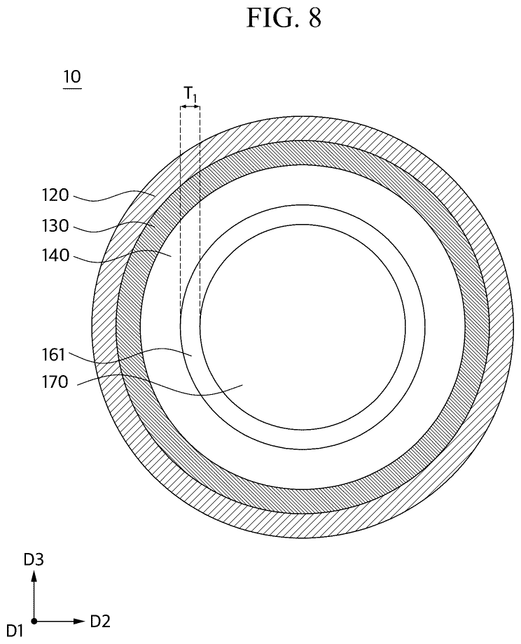

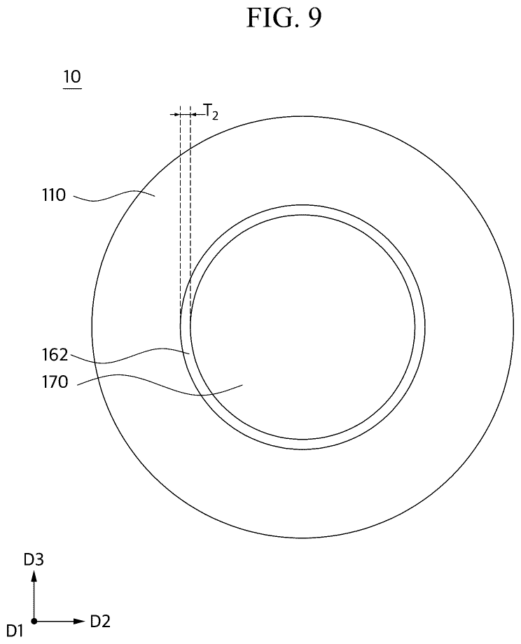

FIG. 7 is an example drawing illustrating a cross-section of the memory device 10 according to a third example embodiment of the present disclosure. FIG. 8 is an example diagram illustrating a cross-section take along line D-D′ of FIG. 7. FIG. 9 is an example diagram illustrating a cross-section taken along line E-E′ of FIG. 7. The description of FIGS. 1 through 4 may be referenced in the description of FIGS. 7 through 9 unless otherwise specified.

In an example embodiment, the ferroelectric layer 140 may be in contact with the channel layer 160 in at least a first region (161, for example). The insulating layer 110 may be in contact the channel layer 160 in at least a second region (162, for example). For example, the memory device 10 may not include the interlayer 150.

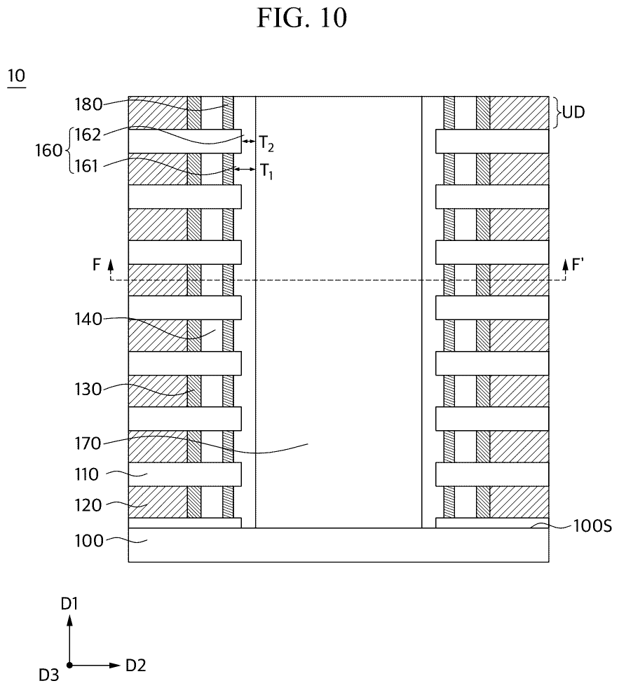

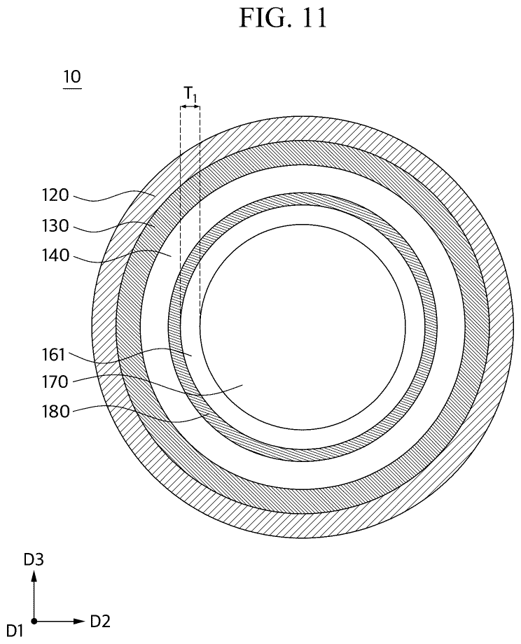

FIG. 10 is an example drawing illustrating a cross-section of the memory device 10 according to a fourth example embodiment. FIG. 11 is an example diagram illustrating a cross-section taken along line F-F′ of FIG. 10. The description of FIGS. 1 through 9 may be referenced in the description of FIGS. 10 and 11 unless otherwise specified.

In an example embodiment, the ferroelectric layer 140 may be in contact with the conductive layer 180 in at least a region, and the conductive layer 180 may be in contact with the channel layer 160 in at least a first region (161, for example). The insulating layer 110 may be in contact the channel layer 160 in at least a second region (162, for example). The memory device 10 may not include the interlayer 150 while including the conductive layer 180.

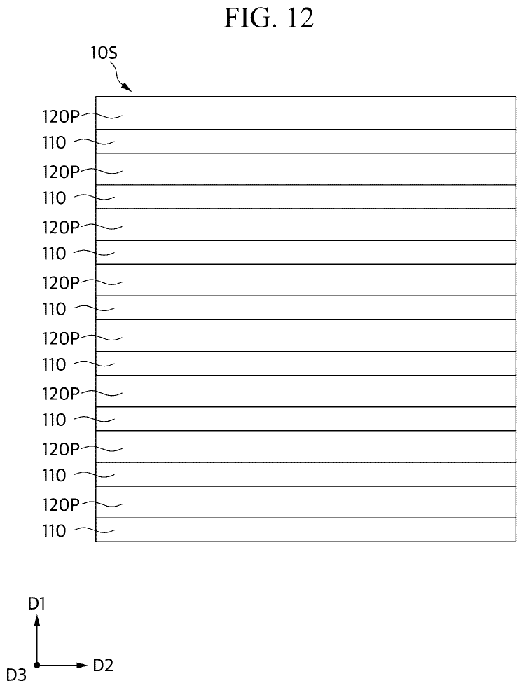

FIGS. 12 through 28 are example drawings showing a method of manufacturing the memory device 10 according to first to fourth example embodiments of the present disclosure. FIGS. 12 through 28 may be described herein with the substrate 100 omitted for convenience and each component may be formed above the substrate 100 or removed except the substrate 100.

Referring to FIG. 12, in an example embodiment, the method for manufacturing the memory device 10 may include forming a laminated body 10S of which the insulating layer 110 and a dielectric layer 120P are alternately laminated in the first direction D1. The dielectric layer 120P may include an insulating material. The dielectric layer 120P may include a material different from a material of the insulating layer 110. The dielectric layer 120P may include the insulating layer 110 and a material with high selectivity. For example, the insulating layer 110 may include an oxide (e.g., silicon oxide) and the dielectric layer 120P may include a nitride (e.g., silicon nitride). In an example embodiment, each of the insulating layer 110 and the dielectric layer 120P may extend in the second direction D2.

Although a predetermined film or layer is not limited in the present disclosure, the predetermined film or layer may be, in an example embodiment, formed through deposition, and the deposition may be performed through, for example, chemical vapor deposition (CVD), physics vapor deposition (PVD), or atomic layer deposition (ALD). When a method other than deposition of a predetermined film or layer used in the art is present, the method may be applied. In addition, although the predetermined film or layer are not particularly limited in the present disclosure, in an example embodiment, the predetermined film or layer may be removed through etching, and the etching may be performed for example, via wet etching which uses phosphoric acid and the like, dry etching, or the like.

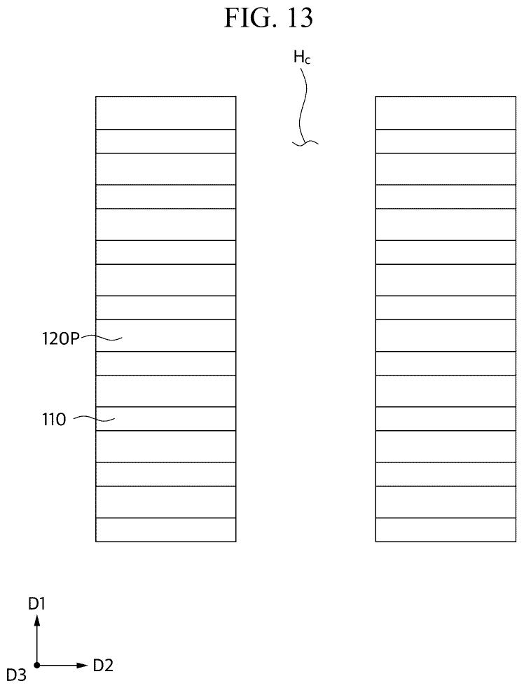

Referring to FIG. 13, in an example embodiment, the method of manufacturing the memory device 10 may include forming a hole Hc in the laminated body 10S. Forming the hole Hc in the laminated body 10S may include forming a mask (not illustrated) on a region other than a region in which the hole Hc is to be formed and removing the laminated body 10S in the first direction D1 from regions other than the region on which the mask is formed through a process such as photo-lithography. However, the method is not particularly limited thereto as long as the hole Hc can be formed in the laminated body 10S.

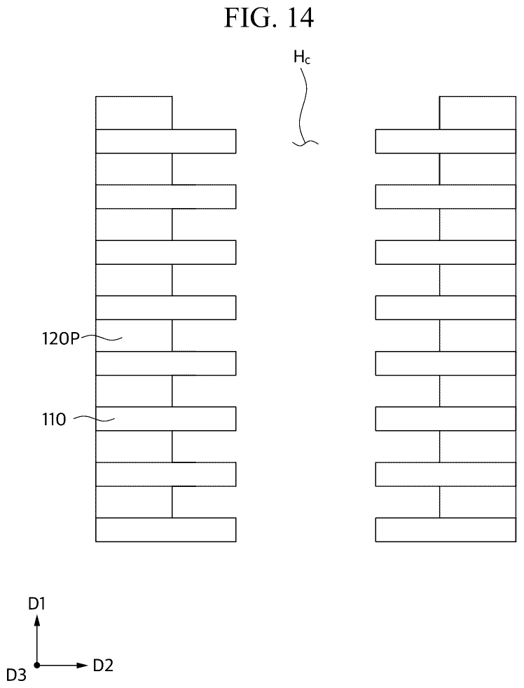

Referring to FIG. 14, in an example embodiment, the method of manufacturing the memory device 10 may include partially removing the dielectric layer 120P in a direction away from the hole Hc in the second direction in which the dielectric layer 120P is extended. Partially removing the dielectric layer 120P may be performed via, for example, pull-pack etching, which is well-known in the art, but this is merely an example.

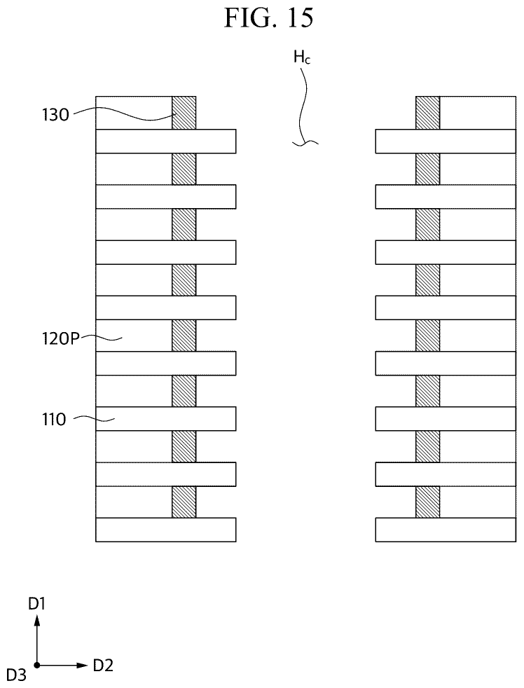

Referring to FIG. 15, the method of manufacturing the memory device 10 may include forming the reactive layer 130 which overlaps with the dielectric layer 120P in at least a region when viewed from the second direction D2 and includes a reactive metal. The reactive layer 130 may be formed to overlap with the insulating layer 110 when viewed from the first direction D1.

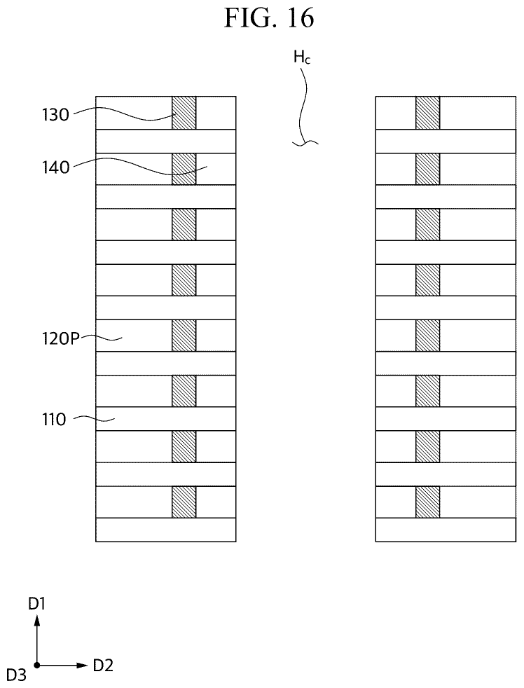

Referring to FIG. 16, in an example embodiment, the method of manufacturing the memory device 10 may include forming the ferroelectric layer 140 on the reactive layer 130. The ferroelectric layer 140 may be formed to overlap with the reactive layer 130 in at least a region when viewed from the second direction D2. The ferroelectric layer 140 may be formed to overlap with the insulating layer 110 when viewed from the first direction D1.

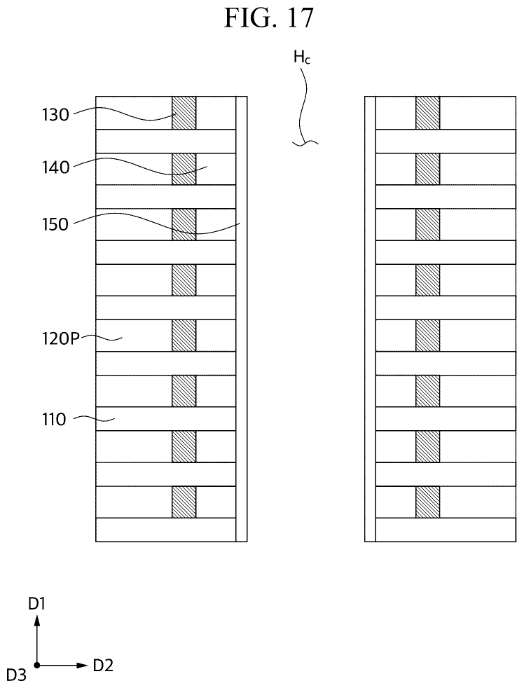

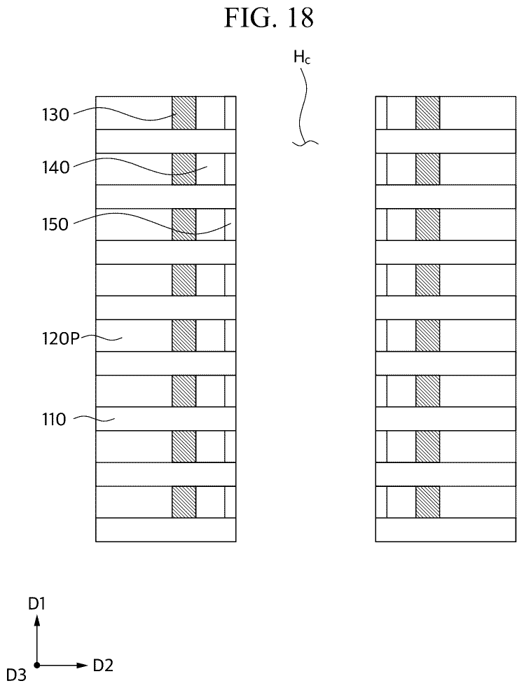

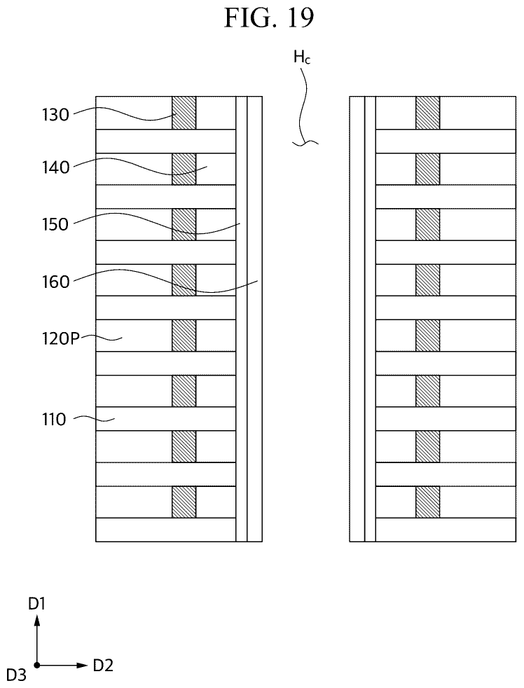

Referring to FIGS. 17 and 18, the method of manufacturing the memory device 10 may include forming the interlayer 150 on the ferroelectric layer 140. The interlayer 150 may include an oxide as described herein. The interlayer 150 may minimize oxidization of the channel layer 160, which is to be formed layer, due to process reasons. Referring to FIG. 17, the interlayer 150 may be formed to extend within the hole Hc in the first direction D1. Referring to FIG. 18, the interlayer 150 may be formed to overlap with the ferroelectric layer 140 in at least a region when viewed from the second direction D2, and here, the interlayer 150 may be formed to overlap with the insulating layer 110 when viewed from the first direction D1. FIGS. 19 through 24 illustrate the interlayer 150 formed in the same manner as FIG. 17. However, it may be apparent to those skilled in the art that the interlayer 150 may be formed using the same method shown in as FIG. 18 as well as by other methods.

Referring to FIG. 19, in an example embodiment, the method of manufacturing the memory device 10 may include forming the channel layer 160 to extend within the hole Hc in the first direction D1. Regarding the channel layer 160, a plurality of regions (e.g., a first region 161 and a second region 162 of FIG. 2) having different thicknesses in the second direction D2 (T₁ and T₂ respectively) may be formed by the reactive layer 130.

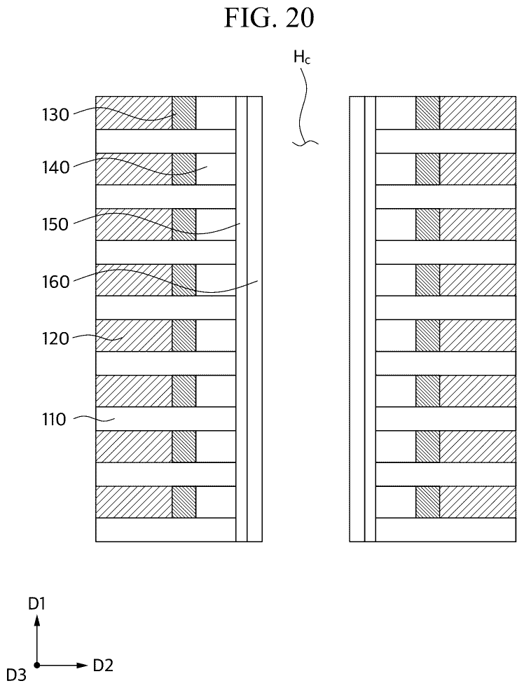

Referring to FIGS. 19 and 20, in an example embodiment, the method of manufacturing the memory device 10 may include replacing the dielectric layer 120P with the gate electrode 120. For example, the gate electrode 120 may be formed via replacement process. The dielectric layer 120P may become a sacrificial layer, and the gate electrode 120 may be formed in replacement. Through this, the memory device 10 according to the first example embodiment described herein may be manufactured.

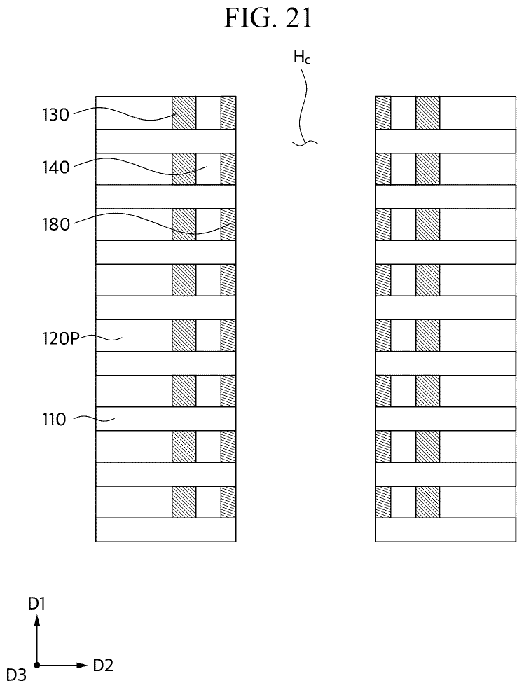

Referring to FIG. 21, in an example embodiment, the method of manufacturing the memory device 10 may include forming the conductive layer 180 on the ferroelectric layer 140. FIG. 21 depicts a process after FIG. 16. The conductive layer 180 may be formed to overlap with the ferroelectric layer 140 in at least a region when viewed from the second direction D2, and here, the conductive layer 180 may be formed to overlap with the insulating layer 110 when viewed from the first direction D1.

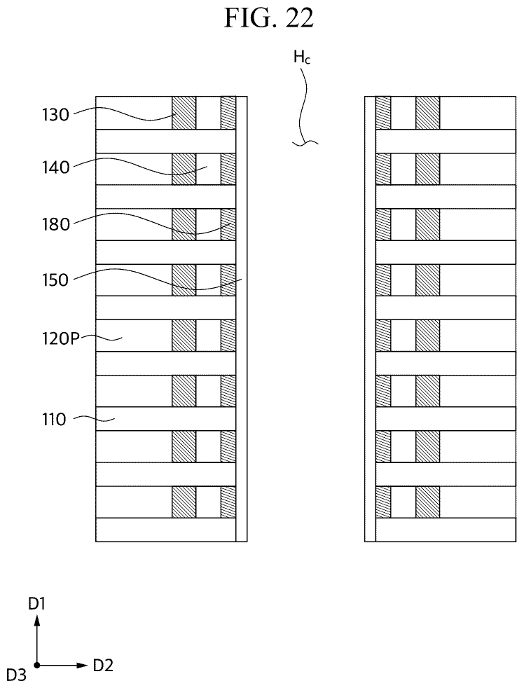

Referring to FIG. 22, in an example embodiment, the method of manufacturing the memory device 10 may include forming the interlayer 150 on the conductive layer 180. The interlayer 150 may include an oxide as the above description. Referring to FIG. 22, the interlayer 150 may be formed to extend within the hole Hc in the first direction D1. Also, the interlayer 150 may be formed in the same manner as FIG. 18, but this is merely an example.

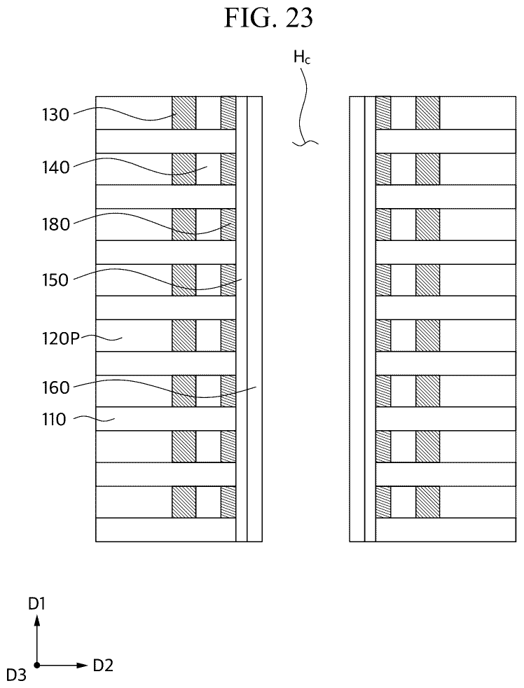

Referring to FIG. 23, in an example embodiment, the method of manufacturing the memory device 10 may include forming the channel layer 160 to extend within the hole Hc in the first direction D1. Regarding the channel layer 160, a plurality of regions (e.g., a first region 161 and a second region 162 of FIG. 2) having different thicknesses in the second direction D2 may be formed by the reactive layer 130.

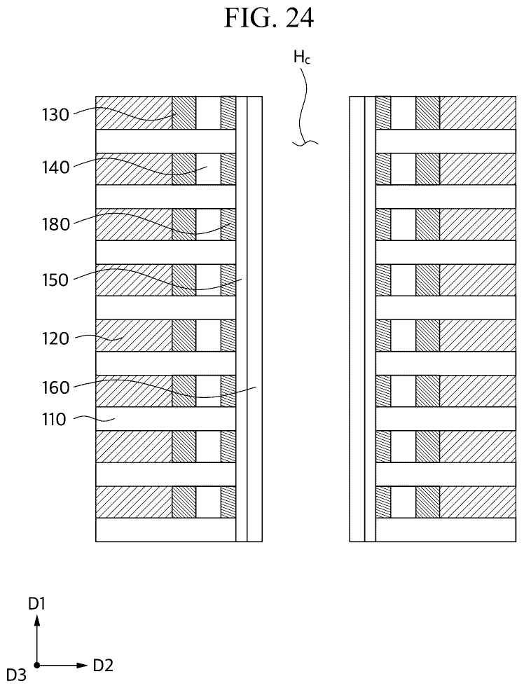

Referring to FIGS. 23 and 24, in an example embodiment, the method of manufacturing the memory device 10 may include replacing the dielectric layer 120P with the gate electrode 120. Through this, a memory device 10 according to the second example embodiment described herein may be manufactured.

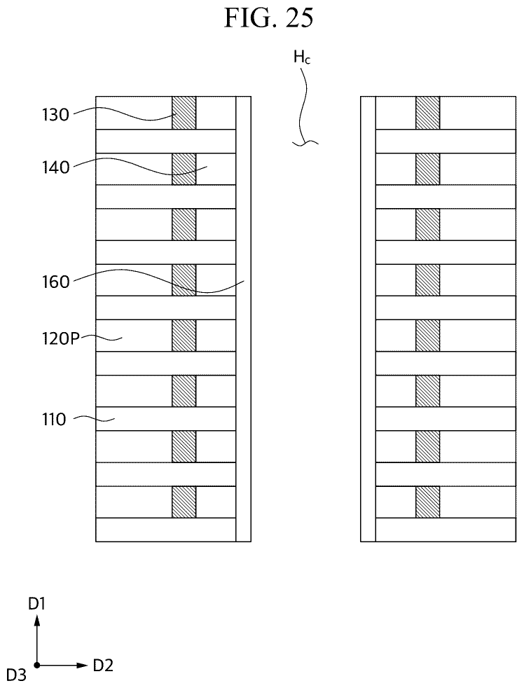

Referring to FIG. 25, in an example embodiment, the method of manufacturing the memory device 10 may include forming the channel layer 160 on the ferroelectric layer 140. The channel layer 160 may be formed to extend within the hole Hc in the first direction D1. FIG. 25 may be a drawing illustrating a process after FIG. 16.

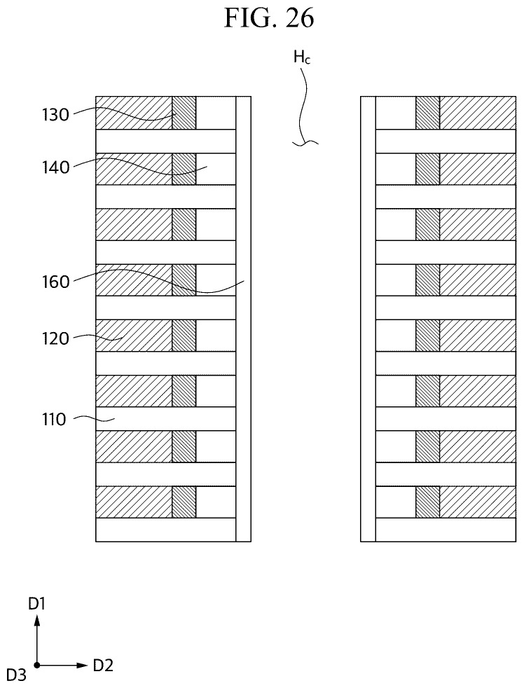

Referring to FIGS. 25 and 26, in an example embodiment, the method of manufacturing the memory device 10 may include replacing the dielectric layer 120P with the gate electrode 120. Through this, a memory device 10 according to the third example embodiment described above may be manufactured.

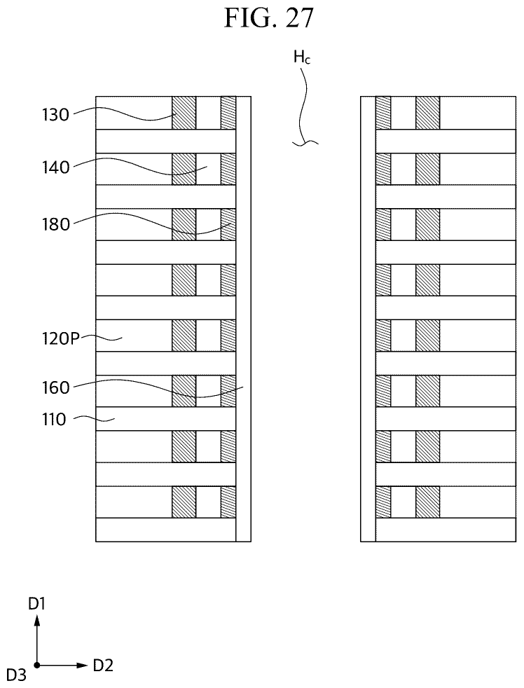

Referring to FIG. 27, in an example embodiment, the method of manufacturing the memory device 10 may include forming the channel layer 160 on the conductive layer 180. The channel layer 160 may be formed to extend within the hole Hc in the first direction D1. FIG. 27 may depict a process after FIG. 21.

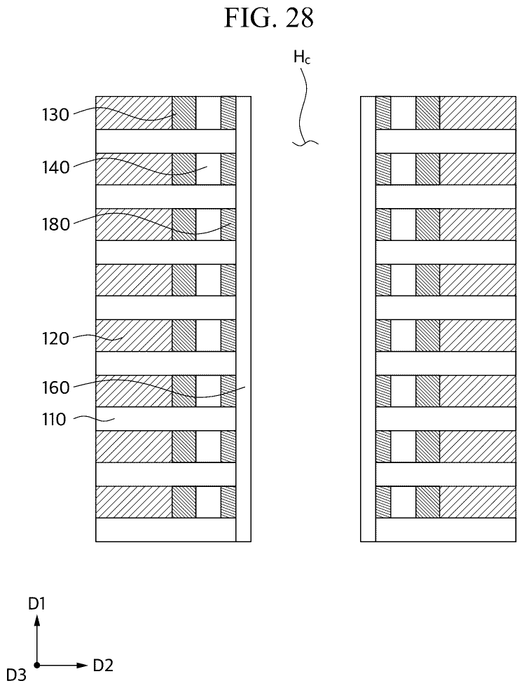

Referring to FIGS. 27 and 28, in an example embodiment, the method of manufacturing the memory device 10 may include replacing the dielectric layer 120P with the gate electrode 120. Through this, the memory device 10 according to the fourth example embodiment described herein may be manufactured.

Although not illustrated in the present drawings, the method of manufacturing the memory device 10 may include forming a filling layer 170 by filling the hole Hc. The filling layer 170 may be formed on the channel layer 160. The filling layer 170 may be formed to extend in the first direction D1. The filling layer 170 may be formed before or after forming the gate electrode 120.

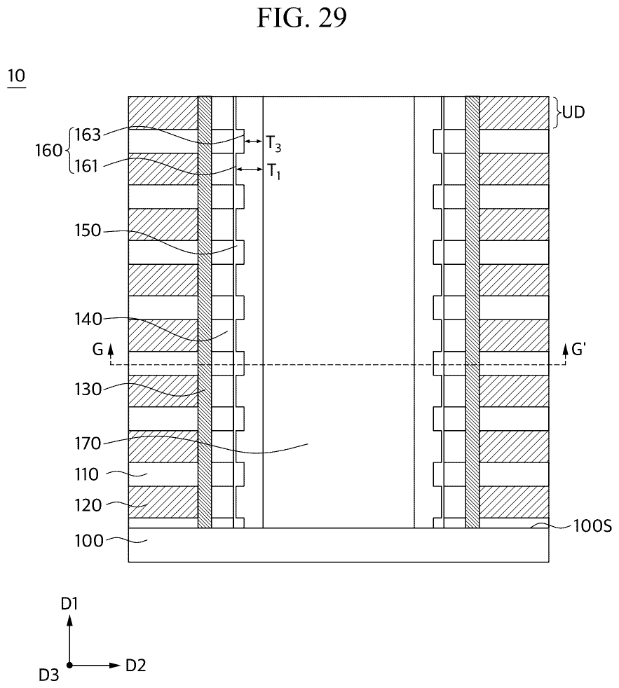

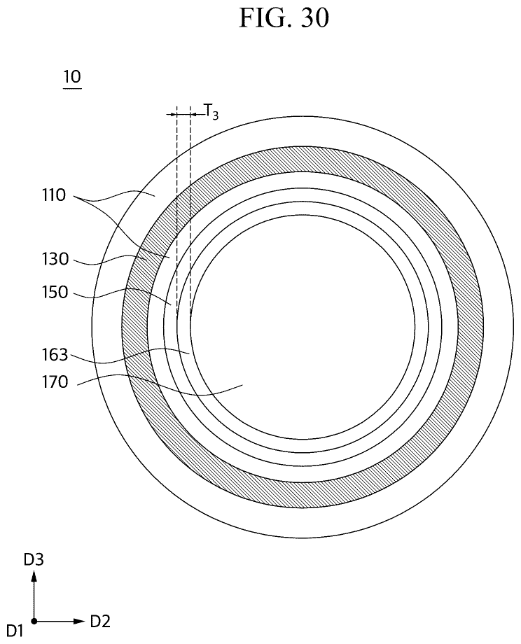

FIG. 29 is an example drawing illustrating a cross-section of the memory device 10 according to a fifth example embodiment of the present disclosure. FIG. 30 is an example diagram illustrating across-section taken along line G-G′ of FIG. 29. The description of FIGS. 1 through 4 may be referenced in the description of FIGS. 29 and 30 unless otherwise specified.

In an example embodiment, the reactive layer 130 may be disposed to extend in the first direction D1, and may overlap with the channel layer 160 in at least a region when viewed from the second direction D2. The reactive layer 130 may be disposed between the gate electrode 120 and the ferroelectric layer 140. The reactive layer 130 may be in contact with the gate electrode 120 in at least a region. The reactive layer 130 may be in contact with the ferroelectric layer 140 in at least a region. The reactive layer 130 may be in contact with the insulating layer 110 in at least a region.

In an example embodiment, the reactive layer 130 may surround at least a portion of the ferroelectric layer 140. The reactive layer 130 may surround at least a portion of the insulating layer 110.

In an example embodiment, the channel layer 160 may include a plurality of regions 161 and 163 having different thicknesses in the second direction D2. A thickness T₁ in the second direction D2 of a first region 161 of the channel layer 160 facing the ferroelectric layer 140 may be greater than a thickness T₃ in the second direction D2 of a third region 163 of the channel 160 that is different from the first region 161.

The thickness T₂ in the second direction D2 of the second region 162 (refer to FIG. 2) that is different from the first region 161 of the channel layer 160 facing the ferroelectric layer 140 when the reactive layers 130 are spaced apart from each other, may be smaller than the thickness T₃ in the second direction D2 of the third region 163 that is different from the first region 161 of the channel 160 facing the ferroelectric layer 140 when the reactive layer 130 is extended in one direction (e.g., the first direction).

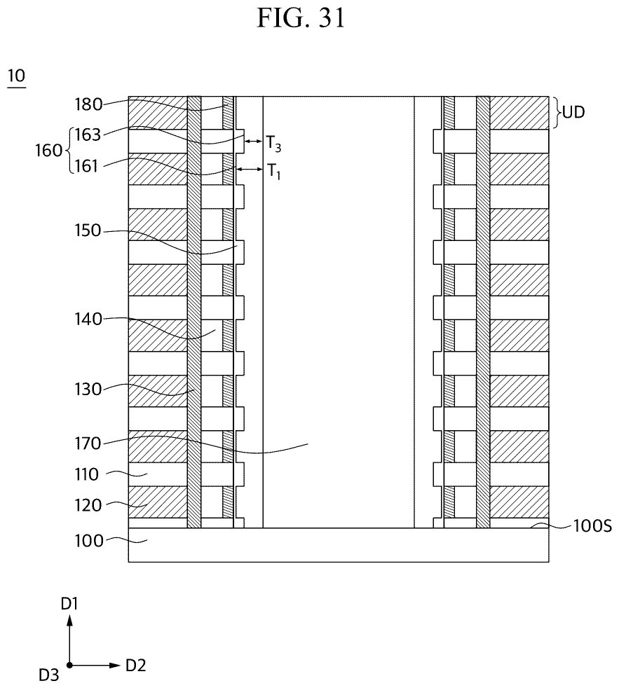

FIG. 31 is an example drawing illustrating a cross-section of the memory device 10 according to a sixth example embodiment of the present disclosure. The description of FIGS. 29 and 30 may be referenced in the description of FIG. 31 unless otherwise specified.

In an example embodiment, the memory device 10 may include a conductive layer 180 that is disposed between the channel layer 160 and the ferroelectric layer 140. The conductive layer 180 may surround at least a portion of the channel layer 160. The conductive layer 180 may be in contact with the ferroelectric layer 140 in at least a region. The description of FIGS. 5 and 6 may be referenced in the description of FIG. 31 except that the reactive layer 130 may extend in the first direction D1.

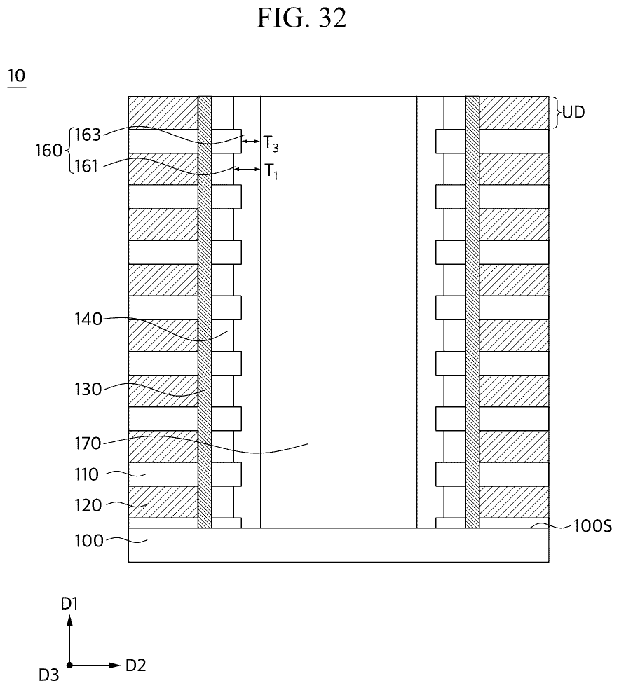

FIG. 32 is an example drawing of a cross-section of the memory device 10 according to a seventh example embodiment of the present disclosure. The description of FIGS. 29 through 31 may be referenced in the description of FIG. 32 unless otherwise specified.

In an example embodiment, the ferroelectric layer 140 may be in contact with the channel layer 160 in at least a first region (161, for example). The insulating layer 110 may be in contact the channel layer 160 in at least a third region (163, for example). For example, the memory device 10 may not include the interlayer 150. The description of FIGS. 7 through 9 may be referenced in the description of FIG. 32 except that the reactive layer 130 may be disposed to extend in the first direction D1.

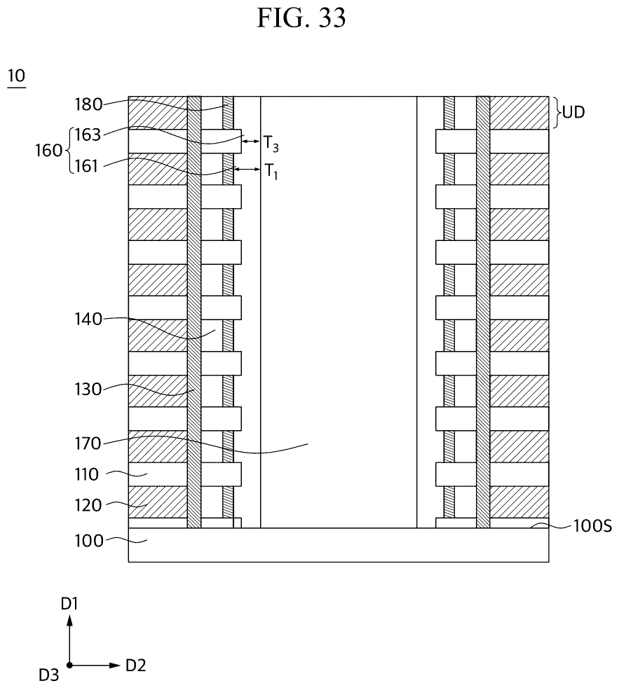

FIG. 33 is an example drawing illustrating a cross-section of the memory device 10 according to an eighth example embodiment of the present disclosure. The description of FIGS. 29 through 32 may be referenced in the description of FIG. 33 unless otherwise specified.

In an example embodiment, the ferroelectric layer 140 may be in contact with the conductive layer 180 in at least a region and the conductive layer 180 may be in contact with the channel layer 160 in at least a first region (161, for example). The insulating layer 110 may be in contact the channel layer 160 in at least a third region (163, for example). The memory device 10 may not include the interlayer 150 while including the conductive layer 180. The description of FIGS. 10 and 11 may be referenced in the description of FIG. 33 except that the reactive layer 130 may extend in the first direction D1.

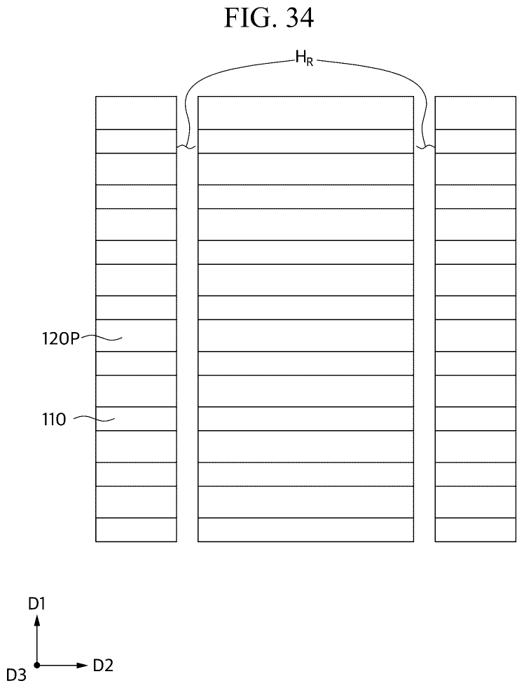

FIGS. 34 through 50 are drawings illustrating a method of manufacturing the memory device 10 according to the fifth to eighth example embodiments of the present disclosure. FIGS. 34 through 50 may be described with the substrate 100 omitted for convenience and each component may be formed above the substrate 100 or removed except the substrate 100. Also, the description of FIGS. 12 through 28 may be reference in the description of FIG. 34 unless otherwise specified.

Referring to FIG. 34, in an example embodiment, the method of manufacturing the memory device 10 may include forming a preliminary hole H_{R} in the laminated body 10S. A plurality of preliminary hole H_{R} including the preliminary hole H_{R} may be formed. Each preliminary hole H_{R} of the plurality of preliminary holes H_{R} may be spaced apart in the second direction D2 and formed by removing the laminated body 10S in the first direction D1. Forming the preliminary hole H_{R} in the laminated body 10S may include forming a mask on regions other than in which the preliminary hole H_{R} will be formed and removing the laminated body 10S in the first direction D1 except the region on which the mask is formed through a process such as photo-lithography. However, the method is not particularly limited thereto as long as the hole Hc can be formed in the laminated body 10S. FIG. 34 may illustrate a process after FIG. 12.

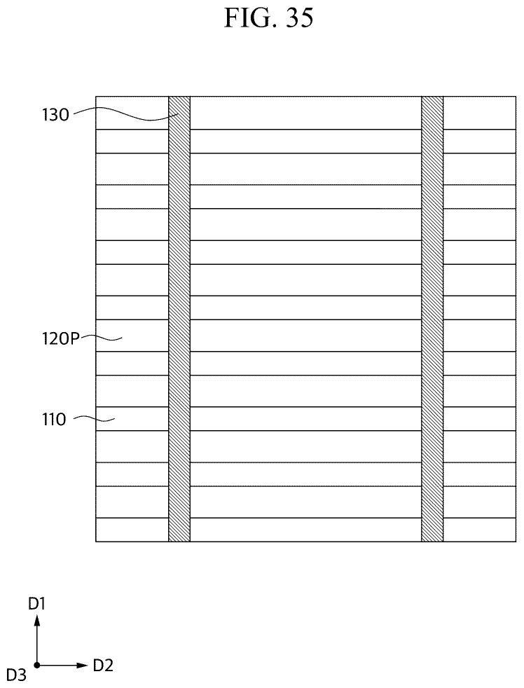

Referring to FIG. 35, in an example embodiment, the method of manufacturing the memory device 10 may include forming the reactive layer 130 including a reactive metal, to fill the preliminary hole H_{R}. The reactive layer 130 may be formed to extend in the first direction D1 along the preliminary hole H_{R}.

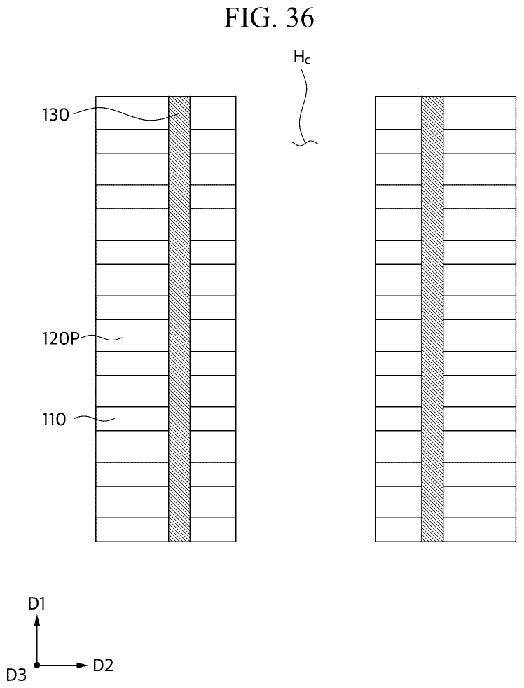

Referring to FIG. 36, in an example embodiment, the method of manufacturing the memory device 10 may include forming a hole Hc in a laminated body 10S. Forming the hole Hc in the laminated body 10S may include forming a mask (not shown) on a region other than a region in which the hole Hc is to be formed and removing the laminated body 10S in the first direction D1 except the region on which the mask is formed through a process such as photo-lithography. However, the method is not particularly limited thereto as long as the hole Hc can be formed in the laminated body 10S. The hole Hc may be formed between the plurality of preliminary holes H_{R} which are filled with the reactive layers 130. The hole Hc may be formed so that a portion of the laminated body 10S is left between the reactive layers 130 filled inside the plurality of preliminary holes H_{R}.

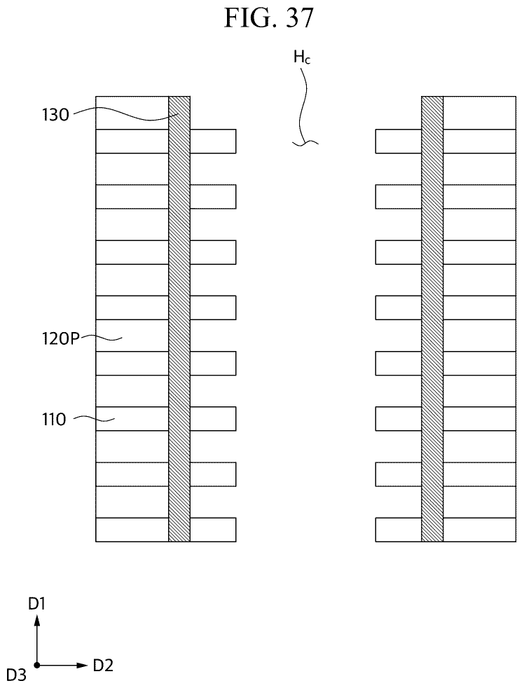

Referring to FIG. 37, in an example embodiment, the method of manufacturing the memory device 10 may include partially removing the dielectric layer 120P in a direction away from the hole Hc in the second direction D2 in which the dielectric layer 120P is extended. Partially removing the dielectric layer 120P may be performed through, for example, a pull-back etching process which is well-known in the art, but this is merely an example. The dielectric layer 120P that is partially removed may be the dielectric layer 120P of a portion of the laminated body 10S left between the reactive layers 130 filling the plurality of preliminary holes H_{R}.

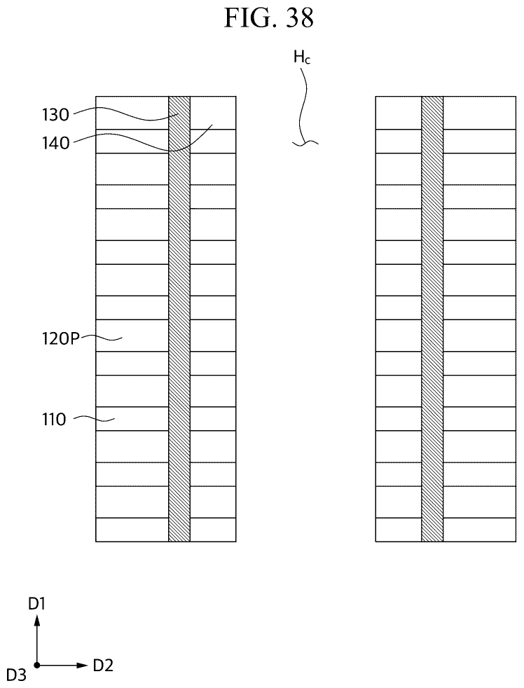

Referring to FIG. 38, in an example embodiment, the method of manufacturing the memory device 10 may include forming the ferroelectric layer 140 on the reactive layer 130. The ferroelectric layer 140 may be formed to overlap with the reactive layer 130 in at least a region when viewed from the second direction D2. The ferroelectric layer 140 may be formed to overlap with the insulating layer 110 when viewed from the first direction D1.

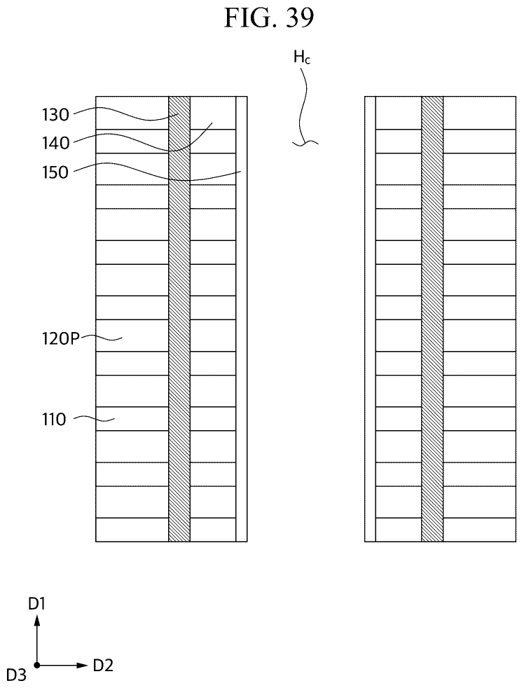

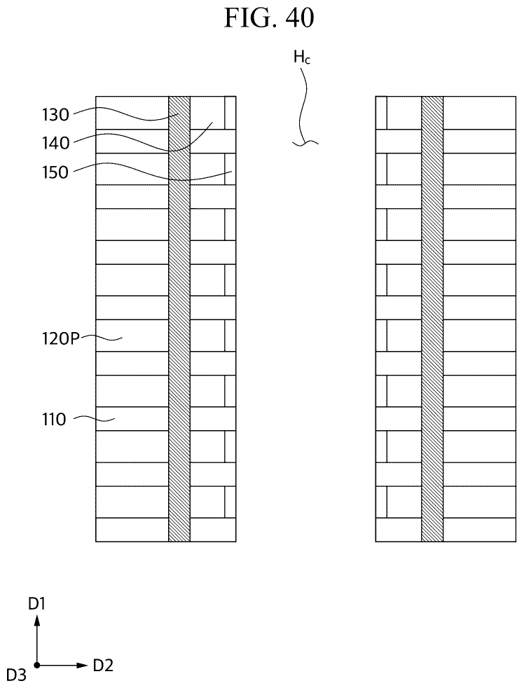

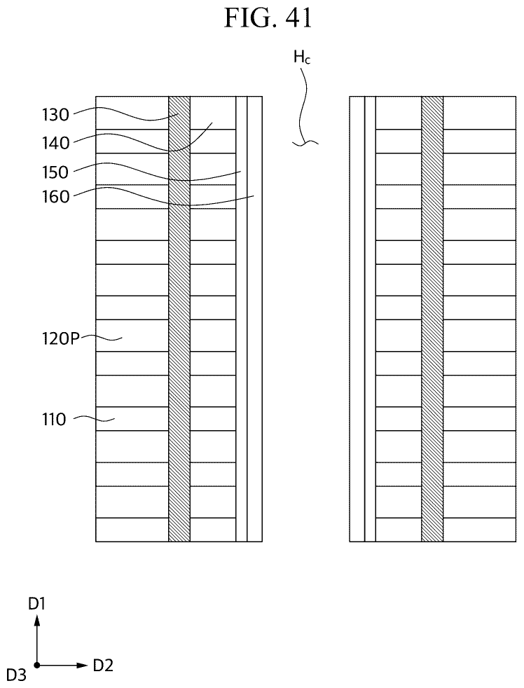

Referring to FIGS. 39 and 40, the method of manufacturing the memory device 10 may include forming the interlayer 150 on the ferroelectric layer 140. The interlayer 150 may include an oxide as described above. Referring to FIG. 39, the interlayer 150 may be formed to extend within the hole Hc in the first direction D1. Referring to FIG. 40, the interlayer 150 may be formed to overlap with the ferroelectric layer 140 in at least a region when viewed from the second direction D2, and here, the interlayer 150 may be formed to overlap with the insulating layer 110 when viewed from the first direction D1. FIGS. 41 through 50 illustrate the interlayer 150 formed in the same manner as FIG. 39, however, it may be apparent to those skilled in the art that the interlayer 150 may be formed using the same method shown in FIG. 40 or other methods may be employed.

Referring to FIG. 41, the method of manufacturing the memory device 10 may include forming the channel layer 160 to extend within the hole Hc in the first direction D1. Regarding the channel layer 160, a plurality of regions (e.g., a first region 161 and a third region 163 of FIG. 29) having different thicknesses may be formed gradually in the second direction D2 by the reactive layer 130.

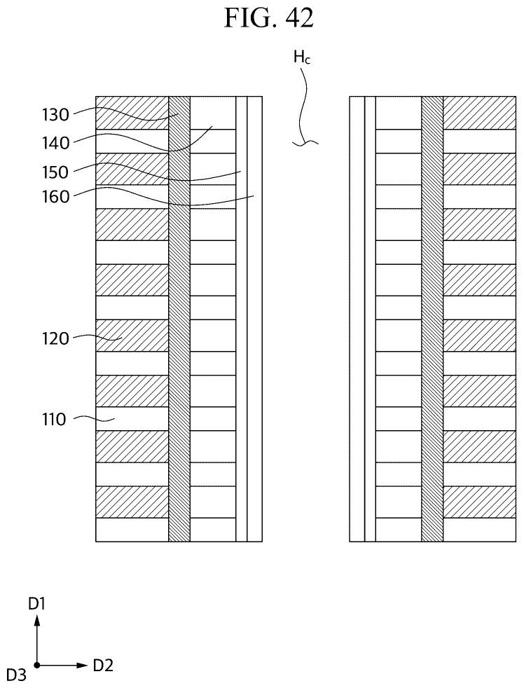

Referring to FIGS. 41 and 42, in an example embodiment, the method of manufacturing the memory device 10 may include replacing the dielectric layer 120P with the gate electrode 120. For example, the gate electrode 120 may be formed through a replacement process. The dielectric layer 120P may become a kind of a sacrificial layer, and the gate electrode 120 may be formed in replacement. Through this, the memory device 10 according to the fifth example embodiment described above may be manufactured.

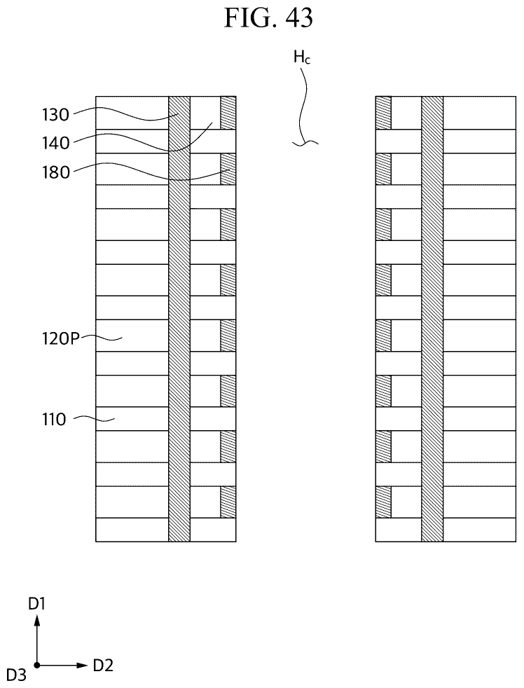

Referring to FIG. 43, in an example embodiment, the method of manufacturing the memory device 10 may include forming the conductive layer 180 on the ferroelectric layer 140. FIG. 43 may be a drawing describing a process after FIG. 38. The conductive payer 180 may be formed to overlap with the ferroelectric layer 140 in at least a region when viewed from the second direction D2, and here, the conductive layer 180 lay be formed to overlap with the insulating layer 110 when viewed from the first direction D1.

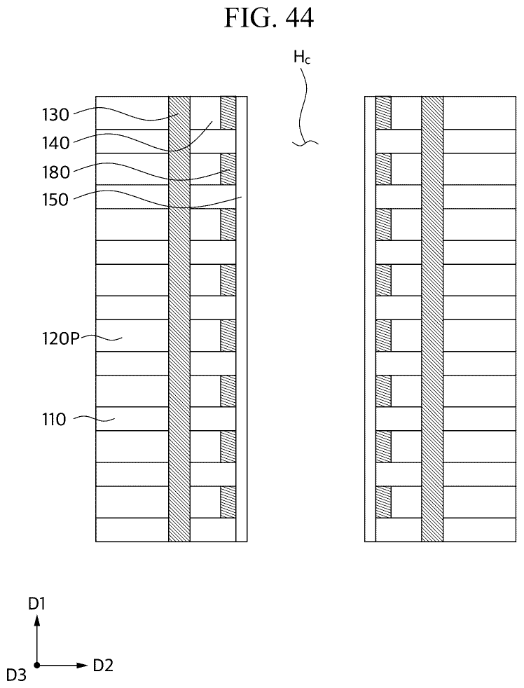

Referring to FIG. 44, In an example embodiment, the method of manufacturing the memory device 10 may include forming the interlayer 150 on the conductive layer 180. The interlayer 150 may include an oxide as described above. Referring to FIG. 44, the interlayer 150 may be formed to extend within the hole Hc in the first direction D1. Also, the interlayer 150 may be formed in the same manner as shown in FIG. 40, but this is merely an example.

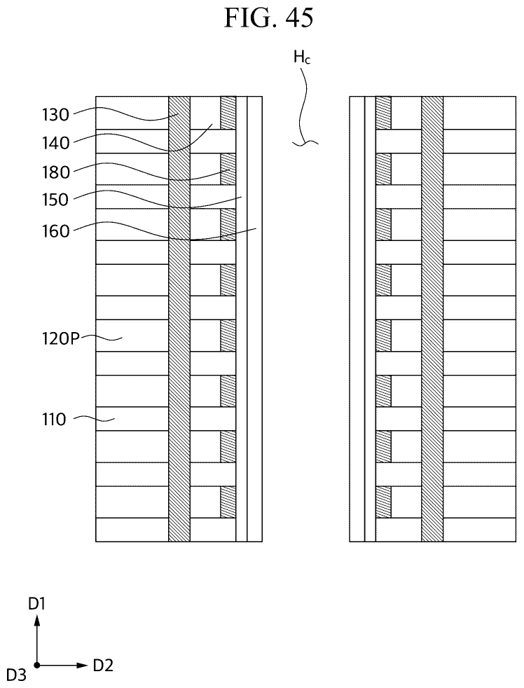

Referring to FIG. 45, in an example embodiment, the method of manufacturing the memory device 10 may include forming the channel layer 160 to extend within the hole Hc in the first direction D1. Regarding the channel layer 160, a plurality of regions (e.g., a first region 161 and a third region 163 of FIG. 29) having different thicknesses may be formed gradually in the second direction D2 by the reactive layer 130.

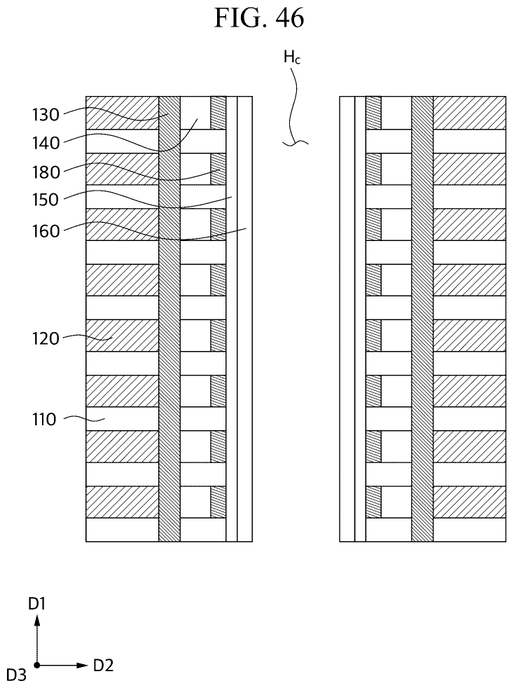

Referring to FIGS. 45 and 46, in an example embodiment, the method of manufacturing the memory device 10 may include replacing the dielectric layer 120P with the gate electrode 120. Through this, the memory device 10 according to the sixth example embodiment described above may be manufactured.

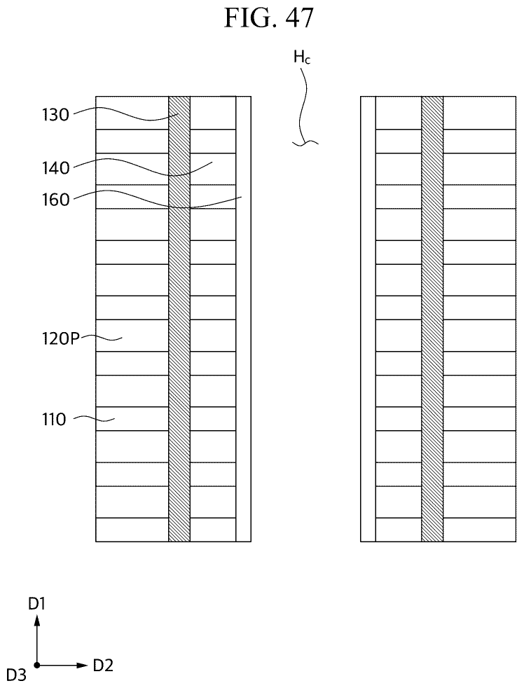

Referring to FIG. 47, in an example embodiment, the method of manufacturing the memory device 10 may include forming the channel layer 160 on the ferroelectric layer 140. The channel layer 160 may be formed to extend within the hole Hc in the first direction D1. FIG. 47 may depict a process after FIG. 38.

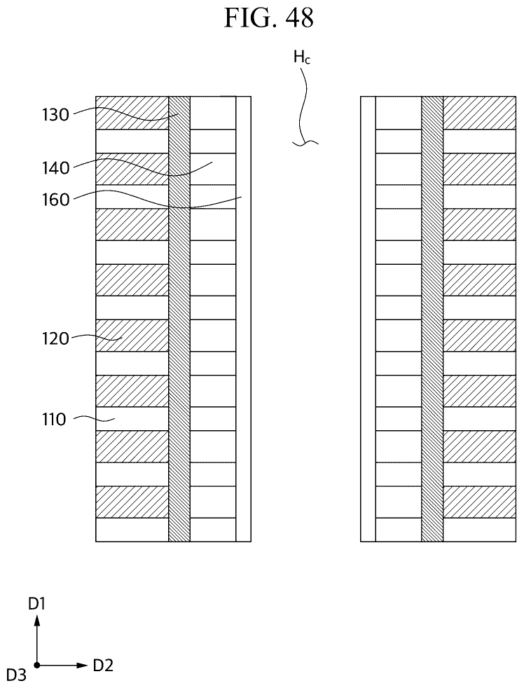

Referring to FIGS. 47 and 48, in an example embodiment, the method of manufacturing the memory device 10 may include replacing the dielectric layer 120P with the gate electrode 120. Through this, the memory device 10 according to the seventh example embodiment described above may be manufactured.

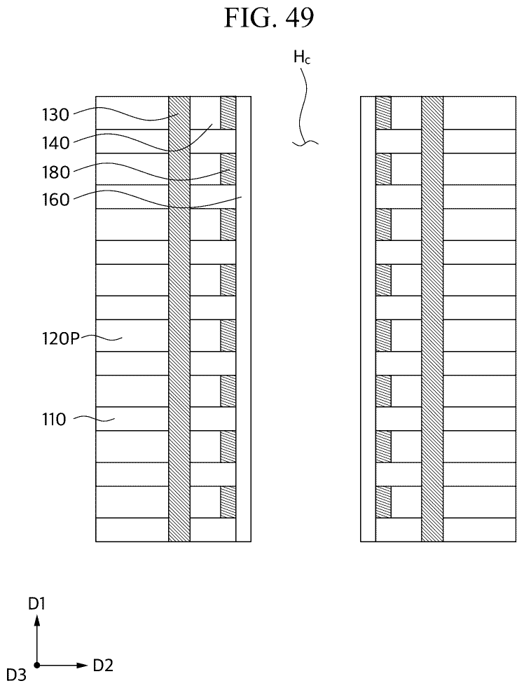

Referring to FIG. 49, the method of manufacturing the memory device 10 may include forming the channel layer 160 on the conductive layer 180. The channel layer 160 may be formed to extend within the hole Hc in the first direction D1. FIG. 49 may be a drawing illustrating a process after FIG. 43.

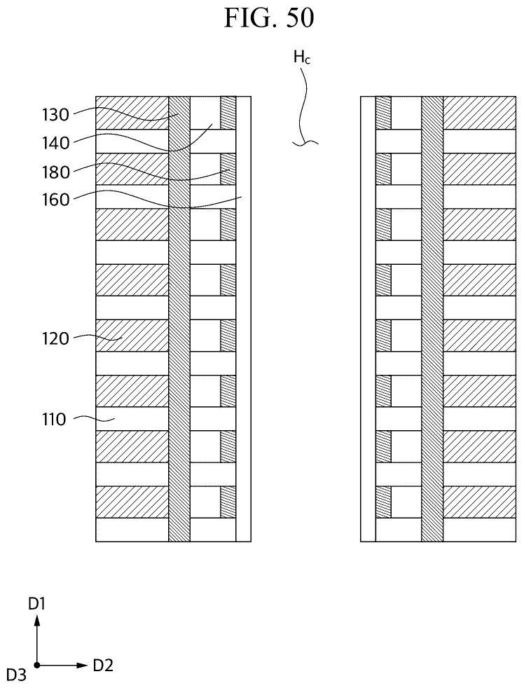

Referring to FIGS. 49 and 50, in an example embodiment, the method of manufacturing the memory device 10 may include replacing the dielectric layer 120P with the gate electrode 120. Through this, the memory device 10 according to the eighth example embodiment described above may be manufactured.

As described above, although not particularly illustrated in the drawings, the method of manufacturing the memory device 10 may include forming the filling layer 170 by filling the hole Hc.

According to example embodiments, it is possible to provide a memory device that is capable of preventing deterioration of cell properties, minimize interruption between cells, and improving polarization properties of a ferroelectric material.

Effects of the present disclosure are not limited to those described above and other effects may be made apparent to those skilled in the art from the following description.

The example embodiments have been described with reference to the accompanying drawings above, however, the present disclosure is not limited to the above example embodiments and may be manufactured in various forms different from each other, and those skilled in the art to which the present disclosure belongs may understand that other embodiments may be implemented without changing the technical spirit of the present disclosure. Therefore, in all aspects, the above-described example embodiments should be understood as mere examples and not as being limitative.

What is claimed is:

1. A memory device comprising:
a substrate;
a channel layer on the substrate and extending in a first direction intersecting a top surface of the substrate;
a plurality of gate electrodes arranged along the first direction, each gate electrode disposed on the channel layer a plurality of ferroelectric layers, each ferroelectric layer between the channel layer and a respective gate electrode; and
a reactive layer between each gate electrode and a respective ferroelectric layer, the reactive layer including a reactive metal,
wherein ferroelectric layers adjacent to each other from among the plurality of ferroelectric layers are spaced apart from each other in the first direction.

2. The memory device of claim 1, wherein the reactive metal includes one or more of titanium (Ti), erbium (Er), cobalt (Co), and cadmium (Cd).

3. The memory device of claim 1, wherein each reactive layer contacts a respective ferroelectric layer.

4. The memory device of claim 1, wherein each reactive layer includes an oxide of the reactive metal.

5. The memory device of claim 4, wherein each reactive layer includes the reactive metal in a greater mass content than a mass content of the oxide of the reactive metal.

6. The memory device of claim 1, wherein the channel layer includes a plurality of regions having different thicknesses in a second direction parallel to the top surface of the substrate.

7. The memory device of claim 6, wherein the plurality of regions of the channel layer include
a first region overlapping the plurality of ferroelectric layers in the second direction, and
a second region different from the first region, and not overlapping the plurality of ferroelectric layers in the second direction,
wherein a thickness in the second direction of the first region is greater than a thickness in the second direction of the second region.

8. The memory device of claim 1, further comprising a conductive layer disposed between the channel layer and the plurality of ferroelectric layers.

9. The memory device of claim 8, wherein a thickness of each gate electrode in a second direction parallel to the top surface of the substrate is greater than a thickness of the conductive layer in the second direction.

10. The memory device of claim 8, wherein the conductive layer is in contact with the plurality of ferroelectric layers.

11. The memory device of claim 1, further comprising an interlayer disposed between the plurality of ferroelectric layers and the channel layer.

12. The memory device of claim 1, further comprising a plurality of insulating layers overlapping with the plurality of gate electrodes when viewed from the first direction.

13. The memory device of claim 12,
gate electrodes adjacent to each other among the plurality of gate electrodes are spaced apart from each other in the first direction, and
the insulating layers are disposed between adjacent spaced apart gate electrodes.

14. The memory device of claim 13, further comprising an interlayer disposed between the plurality of ferroelectric layers and the channel layer and between the plurality of insulating layers and the channel layer.

15. The memory device of claim 13, wherein the plurality of insulating layers are disposed between adjacent ferroelectric layers of the plurality of ferroelectric layers.

16. The memory device of claim 1, wherein the reactive layer is disposed to extend in the first direction and overlap with the channel layer in a second direction parallel to the top surface of the substrate.

17. A method of manufacturing a memory device, the method comprising:
forming a laminated body of an insulating layer and a dielectric layer alternately laminated in a first direction;
forming a hole in the laminated body, the hole extending in a first direction and partially removing the dielectric layer in a second direction in which the dielectric layer is extended, the second direction crossing the first direction;
forming a reactive layer which overlaps with the dielectric layer in the second direction, the reactive layer including a reactive metal;
forming a ferroelectric layer on the reactive layer;
forming a channel layer extending within the hole in the first direction; and
replacing the dielectric layer with a gate electrode.

18. The method of claim 17, further comprising forming an interlayer including an oxide on the ferroelectric layer.

19. The method of claim 17, further comprising forming a conductive layer on the ferroelectric layer.

20. A memory device comprising:
a substrate;
a channel layer on the substrate, extending in a first direction intersecting a top surface of the substrate, and including a plurality of regions having different thicknesses in a second direction parallel to the top surface of the substrate;
a plurality of gate electrodes arranged along the first direction, each gate electrode disposed on the channel layer;
a plurality of insulating layers overlapping with the plurality of gate electrodes when viewed from the first direction;
a plurality of ferroelectric layers each ferroelectric layer between the channel layer and a respective gate electrode; and
a reactive layer between each gate electrode and a respective ferroelectric layer, the reactive layer including a reactive metal,
wherein ferroelectric layers adjacent to each other among the plurality of ferroelectric layers are spaced apart from each other in the first direction,
the reactive metal includes at least one reactive metal selected from the group consisting of titanium (Ti), erbium (Er), cobalt (Co), and cadmium (Cd),
gate electrodes adjacent to each other among the plurality of gate electrodes are spaced apart from each other in the first direction, and
the insulating layers are disposed between adjacent spaced apart gate electrodes among the plurality of gate electrodes.
